(19) United States
(12) Patent Application Publication
(10) Pub. No.: US 2026/0017418 A1
(43) Pub. Date: Jan. 15, 2026

(54) Equivalence Model of the Atom, and other Fundamental Atomic Structures; and a Method for their Construction

(71) Applicants: Julius Young, Bradenton, FL (US); Hector C. Estepan, Lenoir, NC (US)

(72) Inventors: Julius Young, Bradenton, FL (US); Hector C. Estepan, Lenoir, NC (US)

(21) Appl. No.: 18/773,538

(22) Filed: Jul. 15, 2024

(51) Int. Cl. G06F 30/12

(52) U.S. Cl. CPC G06F 30/12

(57) ABSTRACT

The present invention relates to a Machine and Method to Model Electrons, Atoms, Elements, Molecules, Compounds, and other Fundamental Atomic Structures of the Physical Universe. For example, the structure of the new atomic model for each element is an electron configuration consisting of two parts, a) the outer electron configuration containing one or more electrons distributed in one or more predisposed orbitals, orbiting the atom's nucleus and center of mass; and b) an inner electron configuration is the nucleus, containing one or more electrons distributed in one or more predisposed orbitals, orbiting the atom's center of mass.

### BACKGROUND OF THE INVENTION AND PRIOR ART

The Inventors of the Present Invention assert that there are several key drivers that dictate the direction they have taken to create a new Atomic Model, including: a) vectors locate every location in the universe; b) object motion generates Spin; c) the Equivalence between the following phenomena: Mass, Frequency, and Temperature; whereby each is a variation of Energy, with essentially a constant separating them. The present application makes use of said Vectors, Spin and Equivalence to build a new atomic model. These topics will be further explored in the Detailed Description of the Invention section.

Before moving on to discuss the invention, let's first discuss some of the prior art for the Present Invention; whereby much of the prior art comes from the hard sciences and mathematics disciplines in the form of atomic models. Note that a model by its very name is not perfect but is designed to represent the real entity as close as possible; where one is always striving to improve it, to achieve the elusive goal where one cannot tell the difference between the real entity and the model!

Scientists, Philosophers, and others throughout history have presented many Atomic Models to explain the building blocks of the physical universe. While we believe the present invention transcends the prior art of said Atomic Models in several ways, reference to said models is by no means an exhaustive list and has been included for their historical value and for independent review.

Democritus' Atom (Circa 460-370 BC): this Greek philosopher's theory held that everything is composed of “atoms”, which are indivisible; that between atoms, there lies empty space; that atoms are indestructible, and have always been and always will be in motion; [reference: Encyclopedia Britannica and Wikipedia].

John Dalton's Atomic model (circa 1766-1844): he was an English scientist, who came up with an idea that all matter is composed of very small things. Like Democritus, it was an attempt to describe all matter in terms of particles, he called atoms and formed an atomic theory, claiming that:
All matter is made of Atoms; whereby Atoms are indivisible and indestructible;
All atoms of a given element are identical in mass and properties;
Compounds are formed by a combination of two or more different atoms
A chemical reaction is a rearrangement of atoms.

Joseph John Thompson Atomic Model (circa 1904); Joseph was a Cambridge physics professor, discovered the electron in 1897, posited that electrons were negative charged and as such was integral to composing the neutral charged atom; therefore, postulated that protons were a positive charge, and postulated an electron-proton mixture, as in plum pudding.

Rutherford's model of the atom (circa 1911): Rutherford suggested that Thomson's plum pudding model was incorrect. Rutherford posited the atomic nucleus, with a small volume containing the heavy mass positive charge. The lesser mass electron orbits the nucleus, and his model is sometimes known as the planetary atomic model. Rutherford's model had no hydrogen spectral lines explanation. This problem was solved later by a Danish physicist Niels Henrik David Bohr.

Bohr's model of the atom (circa 1915): Bohr's model describes the atom as a positively charged nucleus, which is surrounded by electrons. Electrons travel in circular orbits; attraction is provided by electrostatic forces. Normally occupied energy level of the electron is called the ground state. The electron can move to the less-stable level by absorbing energy. This higher—energy level is called an excited state. The electron can return to its original level by releasing the energy. All in all, when an electron jumps between orbits, it is accompanied by an emitted or absorbed amount of energy (hv).
Problems: a) Bohr's atom could not explain properties of atoms using more than one electron; and b) Bohr's model could not explain the number of fine spectral lines and many of the frequency shifts associated with the Zeeman effect; and c) its inability to explain the rich spectra of multielectron atoms; and d) its inability to generalize the model to multielectron atoms.

Other More Recent Models and Theories: many of he more recent models contain contribution from several individuals. See below:
All particles could be perceived as matter waves. (Louis de Broglie)
Particle wave duality axiom allows the solution to Erwin Schrödinger's wave equation to define the quantum mechanics atomic model.
The uncertainty principle states that the electron's momentum and position cannot be precisely known with accuracy (Werner Heisenberg).
The atom has different electron orbital energy levels (Niels Bohr).
Electrons spin up or down; two electrons in the same orbital must have opposite spins. (the Stern-Gerlach Experiment).

The standard Model of Particle Physics: Key points outlined below:
Currently quarks make up protons, and neutrons, while leptons make up electrons combine to create all matter. Bosons are force carrying particles, interacting with the quarks and leptons.
The Standard Model has four fundamental forces governing the universe:
electromagnetism, the strong nuclear force, the weak nuclear force, and gravity. The photon carries the electromagnetic force. The gluon carries the strong nuclear force binding and stabilizing the nucleus, Strong force. The W and Z bosons carry the weak nuclear force causing nuclear reactions. The graviton, an elementary particle, is proposed to carry the gravitational force;
The Standard Model has the Higgs boson giving mass to quarks, leptons, bosons, and the W and Z bosons, but does not have a mechanism to gives mass to rarely interacting neutrinos. The standard model cannot explain dark matter and dark energy.

Nuclear Shell Model (Published in 1950) by Maria Goeppert Maye, a theoretical physicist, developed a mathematical model for the structure of nuclear shells, which she published in 1950 and received a Nobel Prize in 1963. Her model explained why certain numbers of nucleons (i.e. 2, 8, 20, 28, 50, and 126) in an atomic nucleus result in particularly stable Element configurations.

In light of the strengths and some of the shortcomings exhibited by the above list of prominent Atomic Models discussed, there is a need for the present Equivalence Model, and as an atomic model it: a) explains the atom's size and mass differences between the heavier inner or nucleus configuration and the lighter outer electron configuration of the atom, b) achieves, maintains and explains the atom's charge neutrality; c) examines, through observation, study, and research, the promise of exposing answers to puzzling phenomena such as spectral lines; atomic particle bonding to form electrons, which bond together to form elements, which in turn bond together to form molecules, and compounds; and d) demonstrates how the long established laws of physics not only applies to very large bodies like moons, planets, and stars but also applies to much smaller particles like the Atom!

### Disclosure

In the interest of full disclosure, the Inventors have listed books, authored as outlined below. Inventors also assert that said materials do not rise to the level of prior art to the Present Invention Application.

### BOOKS

Estepan, Hector: A MATHEMATICS UNIFIES THE UNIVERSE, Published BY Bardolf & Company, 2020
Estepan, Hector: A UNIFICATION THEORY OF THE UNIVERSE, Published by Bardolf & Company, 2013

### SUMMARY OF THE INVENTION

In summary, the Present Invention, using only electrons, comprises the binding of a plurality of electrons together in predisposed electron configurations of each element to create atoms, molecules, compounds, and other fundamental atomic structures of the physical universe.

Through spacetime rearrangements, the new atomic model opens the portals to fully understand the key components of the Present Invention, and equally important why this novel approach to building a new and improved model of the atom is relevant. Some of the invention's most important features which translate into building blocks, will be illustrated via the use of a Mathematical Universe which enables the removal of much of the complications preventing a clear understanding of complex real-world subjects. Then said features will be shown to remain applicable in the Real Universe and finally used in the development of the new Model of the Electron and the building of the Atom, Molecules, compounds, and other fundamental atomic structures of the physical universe, but ultimately the spacetime rearrangements creates the new atomic model.

Using said Mathematical Universe as a “staging area”, some of its key features are outlined below; and the role they play in building atomic structures in the new Atomic Model is more fully explained under the Detailed Description section.
The Mathematical Universe will use a spherical, and cartesian coordinate system as staging areas, starting with a Sphere of radius R, volume V, and motion V/t, along the positive x axis. Said motion produces a right-hand torque orthogonal to the direction of motion, which results in a Spinning Sphere.
Given the Mathematical Universe, Newton's first two laws of motion, spherical and cartesian coordinates, volume, velocity, acceleration, spin, rotation, space, and time, it can be shown that such diverse very large moving bodies as the sun, moon, planets to extremely small moving bodies as atoms, and electrons are all governed by the same laws of physics.
The role that the Fine Structure Constant: α=1/137 and Cosmic Microwave Background Radiation (CMBR) play in building the atomic model of the Present Invention will be explained.
The Inventors assert that Photons are a corner stone of the new Atomic Model because, as one will soon find out in a subsequent discussion in the detailed description section of the present invention, the CMBR is where the basic building blocks called Photons come together resulting in repeated collisions with commensurate increases in vibrational frequencies that collectively populate the CMBR with a myriad of Electrons of all sizes and masses, which in turn act as an Electron pool from which the elements source the electrons needed to populate its orbitals to make each Element, from Hydrogen to Oxygen and Carbon to the Elements found at what we know in today's science as the end of the Periodic Table and beyond!
The Equivalence established among Energy, Mass, Frequency, and Temperature as exhibited in established scientific laws through research, experimentation, testing, and deep thinking, will be explained in the DETAILED DESCRIPTION OF THE INVENTION that follows. Note that said Equivalence is exhibited in such equations as:
   Einstein's E=mc² for the Energy−Mass relationship; where c, the speed of light and m is mass;
   Einstein/Planck's equation E=hf for the Energy−Frequency relationship; where h is Planck's constant, and f is the frequency;
   E=k_{B}T for the Energy−Temperature relationship; several Physicists and others contributed to the development of this equation; where kB is Boltzmann's constant, and T is absolute temperature (Kelvin).
The Impact of Spin and Collision on Energy, Mass, Frequency, and Temperature in view of said Equivalences will also be fully explained.

Given the above features as a foundation, the structure of the new atomic model for each element is an electron configuration consisting of two parts, a) the outer electron configuration containing one or more electrons distributed in one or more predisposed orbitals, orbiting the atom's nucleus and center of mass; b) an inner electron configuration is the nucleus, containing one or more electrons distributed in one or more predisposed orbitals, orbiting the atom's center of mass. However, there are notable differences between the outer and inner configurations; such as:
the size of the electrons (using their radii as a gage) in the electron configuration, for example, when occupied, the outermost orbital of the nucleus contains electrons which are correspondingly smaller by the square of said fine structure constant, α; or 1/α²=1/18,769 times smaller than the size of the corresponding electrons in the outermost orbital of the outer electron configuration due to the dramatic increase (by a factor of 18,769) in both the electron's spin and orbiting frequencies. Note that the size difference remains true between electrons in correspondingly deeper inner and outer orbitals.
the mass of the electrons, for example in the outermost orbital of the nucleus is considerably greater by the square of the inverse of the fine structure constant; whereby, the square of its inverse is 1/α²=18,769 times greater than the mass of the electrons in the outermost orbital of the outer electron configuration. This is due to the dramatic increase (by a factor of 18,769) in both the electron's spin, orbital and/or vibration frequencies. Note that the mass difference remains true between electrons in correspondingly deeper inner and outer orbitals.

### BRIEF DESCRIPTION OF DRAWINGS

FIG. 1 (Sphere) is a perspective view of the Mathematical Universe 110 with traditional reference numbers identifying the various components of the drawing as well as letter designations for familiar components in the drawings; thus, showing a Sphere 130 with volume V 107, and radius rₒ 121; located in its 3-dimensional Cartesian Coordinate System. Note that for the sake of clarity, said letter designations will be included in follow-on drawings, as appropriate.

FIG. 2 (Moving Sphere) shows the same perspective view as that of FIG. 1 but shows the sphere's motion υₒ 122, moving parallel to the x axis 112, in the positive direction, designated by the reference number 122. Also note the positive y-axis 116, and positive z-axis 114 in the 3-dimensional Cartesian Coordinate System.

FIG. 3 (Spinning Moving Sphere)) Shows a perspective view of the Sphere 130 of FIG. 2; which is also spinning with a spin frequency fₒ 126.

FIG. 4, shows a closeup of the same perspective view of a Sphere 130 as that of FIG. 3, in the Mathematical Universe 110; and showing the center of a 3-dimensional Spherical Coordinate System, with a location vector R_{υ}, from center 000 to the center of the Sphere, a radius r. 121, polar angle θ 119, and azimuthal angle Φ 120 respectively.

FIG. 4A (Closeup of a Moving Sphere), shows the Sphere 110 of FIG. 4, fully translated to the center of the spherical coordinate system.

FIG. 4B (Closeup of a Moving Sphere) shows the same perspective view as that of FIG. 4A; however, the perspective has been moved from the Mathematical Universe 110 to the Real Universe 220, with the Sphere representing an Electron with designation 140 instead of 130 and radius designated as R 121 instead of rₒ; however the essential aspects of the Mathematical Universe fully apply to the Real Universe.

FIG. 5 (Mathematical Model of CMBR) a perspective view of the Mathematical Universe 110 with an ocean of spinning spheres 130 in motion, which will be shown to be the mathematical equivalent of Photons in the Real Universe 220.

FIG. 5A (moving Sphere representing one of the spinning Spheres of FIG. 5) a perspective view of the Mathematical Universe 110 shows the mathematical equivalent of a Photon spinning sphere 130 in motion, (with H, B, and E Vectors) and the resulting collisions will be shown to create pools of Electrons in various sizes and masses in the Real Universe 220.

FIG. 6 Shows (H, B, and E Vectors) a perspective view of the Real Universe 220 showing the enlarged Sphere 140 (the Electron) from FIGS. 4B and 6, with the location of the Magnetic Field Intensity Vectors H 146, the Magnetic Flux Density Vectors B 147, and the Electric Field Vectors E 148.

FIG. 7 (Example: New Model of Atom; Real Universe 220) shows a perspective view of the new model of an Atom using the simplest atom, Hydrogen as an example with a single outer and a single inner electron orbiting a common center of mass. The key components of the Hydrogen model are its outer Electron, a sphere 140 in the 1^{st} orbital (i=1, its outermost orbit), orbiting around the atom's nucleus and center of mass at speed c, while spinning on its axis. Similarly, the Hydrogen atom's inner Electron, is a sphere 139 in the Nucleus' 1^{st} orbital (j=1, the nucleus outermost orbit), orbiting around the atom's center of mass at speed c, while spinning on its axis. The Atom's mass and size, for both outer and inner configurations was summarized in the above Summery of the Invention section and will be further described in the Detail Description section.

FIG. 8 (Making of a Molecule, step 1; Real Universe 220) shows a perspective view of two Hydrogen Atoms 225 and 226, beginning the process of forming a Hydrogen Molecule in FIGS. 8, 8A through 8D.

FIG. 8A (Making of a Molecule, step 2; Real Universe 220) shows a simplified diagrammatic view of the two Hydrogen atoms, each having come under the influence of each other's opposite spin attraction, which in turn draws them ever closer to each other.

FIG. 8B (Making of a Molecule, step 3; Real Universe 220) shows a perspective view of the Hydrogen atoms of FIG. 8; but with the Atoms drawn considerably closer to each other due to their opposite spin attraction.

FIG. 8C (Making of a Molecule, step 4; Real Universe 220) shows the simplified diagrammatic view of the two Hydrogen Atoms of FIG. 8A; but with double arrowed lines emphasizing the strong two way Spin Attraction between the two Atoms.

FIG. 8D (Making of a Molecule, step 5; Real Universe 220) show the simplified diagrammatic view of the Hydrogen Molecule encapsulated in its spherical cocoon 164 that results from the strong spin attraction between the two Hydrogen Atoms as described in FIGS. 8 thru 8C.

### DETAILED DESCRIPTION OF THE FIRST EMBODIMENT OF THE INVENTION

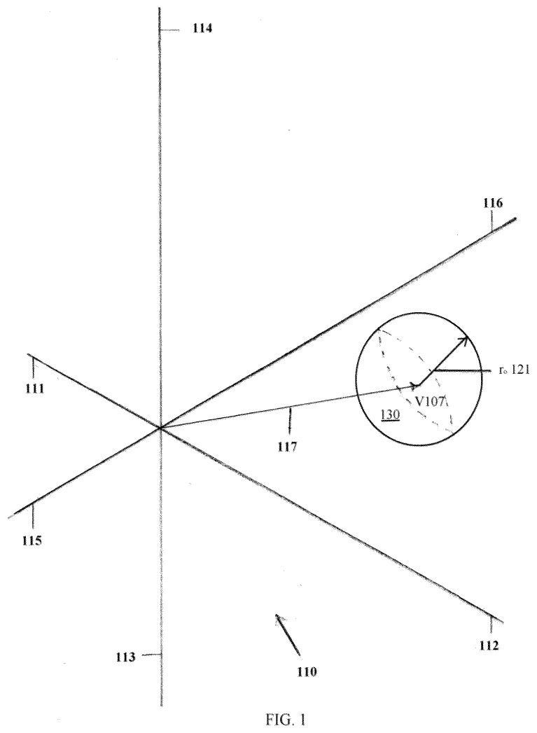

Referring to the drawings listed above (i.e., FIGS. 1-4, 4A-4B, 5, 5A, 6-8, and 8A-8D); the first embodiment of the present invention is a new Atomic Model called the Equivalence Model of the Atom, and other Atomic Structures of the Physical Universe. The Equivalence Model can be used as a tool by Scientist, Researchers and others interested in the study of the physical universe, much like prior models, which were introduced in the opening paragraphs of the present patent application.

To describe the key features and concepts of the Present Invention in detail, we will continue to use the Mathematical Universe as a staging area to illustrate how said features translate into building blocks and finally are used in the development of the Equivalence Model.

Before describing the first embodiment, a detailed structure of the new atomic model, several Key features and concepts of the Present Invention are discussed under the following topics, then the Equivalence Model will be fully explained.
The Mathematical Universe and the Mathematical sphere;
Action at a Distance;
The Spinning Sphere and its connection to the Electric Charge, Cosmic Microwave Background Radiation (CMBR), and Mass;
Equivalence of Energy, Mass, Frequency, and Temperature;
Impact of Collision on Energy, Mass, Frequency and Temperature;
The Fine Structure Constant: α=1/137.
The Relationship Between B, E, and v.

The Mathematical Universe: referring to FIG. 1, the first task in describing the Mathematical Universe 110, is to introduce the Mathematical Sphere 130 (FIGS. 1, 2, 3, and 4, hereafter referred to as the Sphere). The Mathematical Universe 110 with the use of such basic building blocks as the Sphere 130, will be used as a “staging” area to develop and build a new model of the Atom and other fundamental atomic structures of the physical Universe.

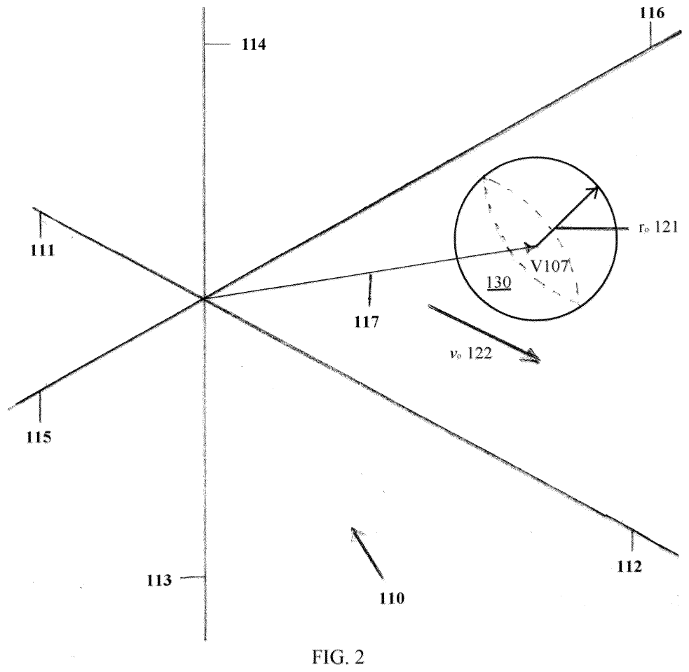

We start with a Sphere 130 of volume V 107 and radius r. 121, moving at a constant speed of υₒ 122 (see arrow in FIG. 2). By introducing said Sphere 130 with volume, motion, and time, together with the fundamental laws of physics that dictate the Equivalence of mass with several alternative phenomena; such as energy, frequency, and temperature; thus, the Applicants will later show for example that using said parameters of the Sphere 130 leads to the introduction of both mass and charge to the Sphere in the Mathematical Universe.

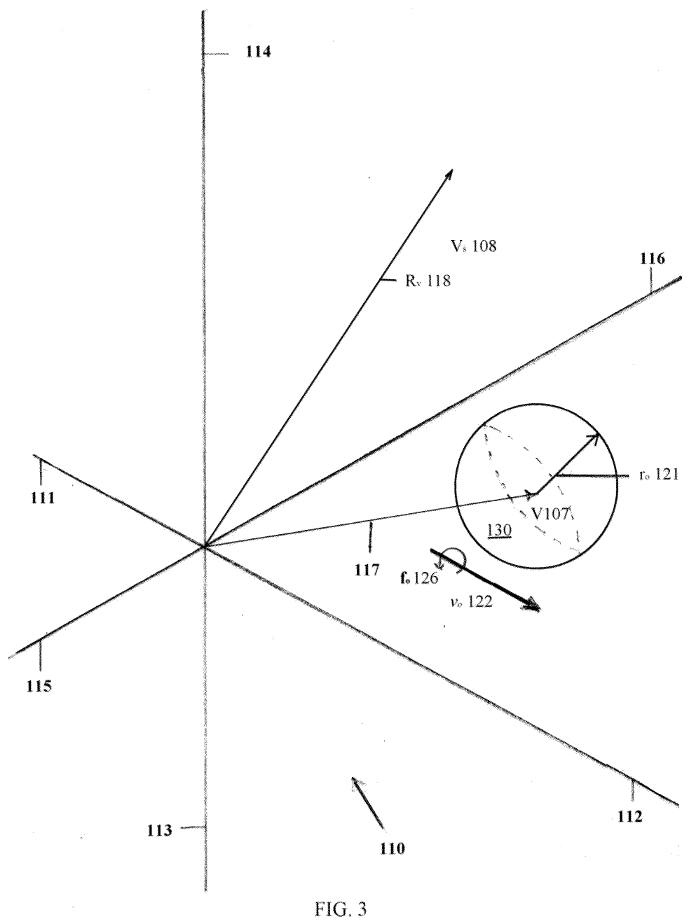

Action at a Distance: in the Mathematical Universe 110 there are only two Volumes (FIG. 3), each mutually exclusive of the other. There is the volume of space V_{S} 108 and there is the volume V 107, of the Sphere 130, where V=(4/3)πrₒ³, therefore the total volume of the universe is V_{U}=V+V_{S}. Using three-dimensional coordinates, the volume vector R_{υ} 118, R_{υ}=xiₓ+yi_{y}+zi_{z} locates every position in the Mathematical Universe, including the Mathematical Sphere 130. Every point and every object can be located by the vector R_{υ} 118; which can also be represented as:

$${R}_{υ} = {Xi}_{x} + {Yi}_{y} + {Zi}_{z}$$

$$where$$

$$X = {f}_{x} ( x ) \neq 0 ,$$

$$Y = {f}_{y} ( y ) \neq 0 ,$$

$$and$$

$$Z = {f}_{z} ( z ) \neq 0$$

Continue referring to FIG. 3. In the Mathematical Universe 110, a moving object is the volume V/f(t) where f(t)≠0 is any time function. The interesting aspect is that the object's movement exhibited by V/f(t) causes the space movement exhibited by V_{S}/f(t), because V 107, and V_{S} 108 (see FIG. 3) are mutually exclusive. This is extremely important, but to see this think of the object having its coordinates R_{υ} 118, where R_{υ}=Xiₓ+Yi_{y}+Zi_{z} and space having its coordinates Vₛ 108, Vₛ=xiₓ+yi_{y}+zi_{z} and V_{U} although infinite is constant, hence moving V 107 must move V_{S} 108. Why is this so crucial? Because any movement V makes it transmit this movement to every space coordinate, and this is “action at a distance”! Notice that the only energy in action at a distance is the energy or force used to move V.

Since all volumes must have the vector R_{υ} 118, where R_{υ}=Xiₓ+Yi_{y}+Zi_{z} then V/t is nothing more than A(Xiₓ+Yi_{y}+Zi_{z})/t, where A (not shown) is the cross sectional area orthogonal to the volume's vector; a volume moving along the iₓ direction, with constant speed vₒ 122 which is the vector Xiₓ, but also Xiₓ/t, or vₒ=X/t and this leads to the distance—time relationship X=vₒt, which is a very simple equation but states that because vₒ is constant; X, space, is proportional to t, time; thus time and space are equivalent, with essentially a constant separating them. Also note that since the volume is moving, it is spinning with a spin frequency fₒ 126 due to the torque applied orthogonal to the direction of travel.

A key take-away from the above discussion is that a moving object has different times along the direction of motion.

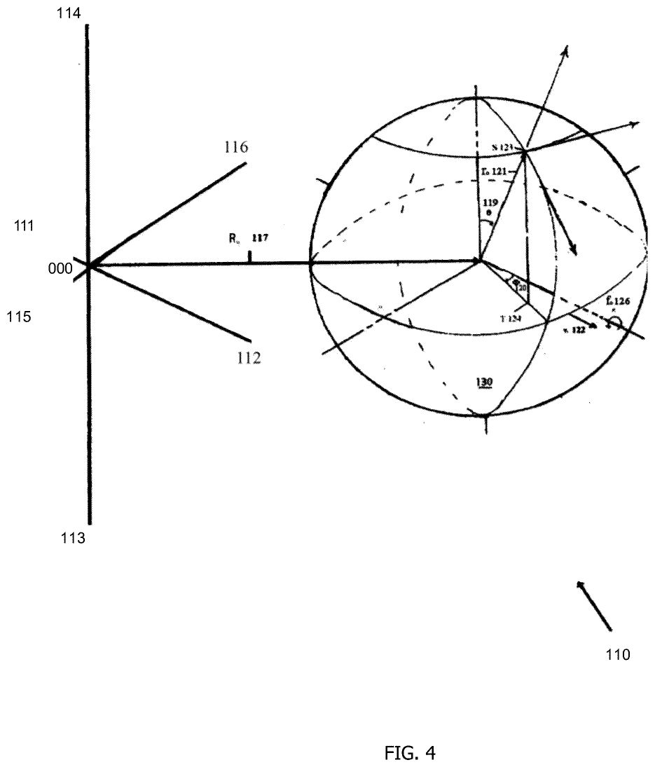

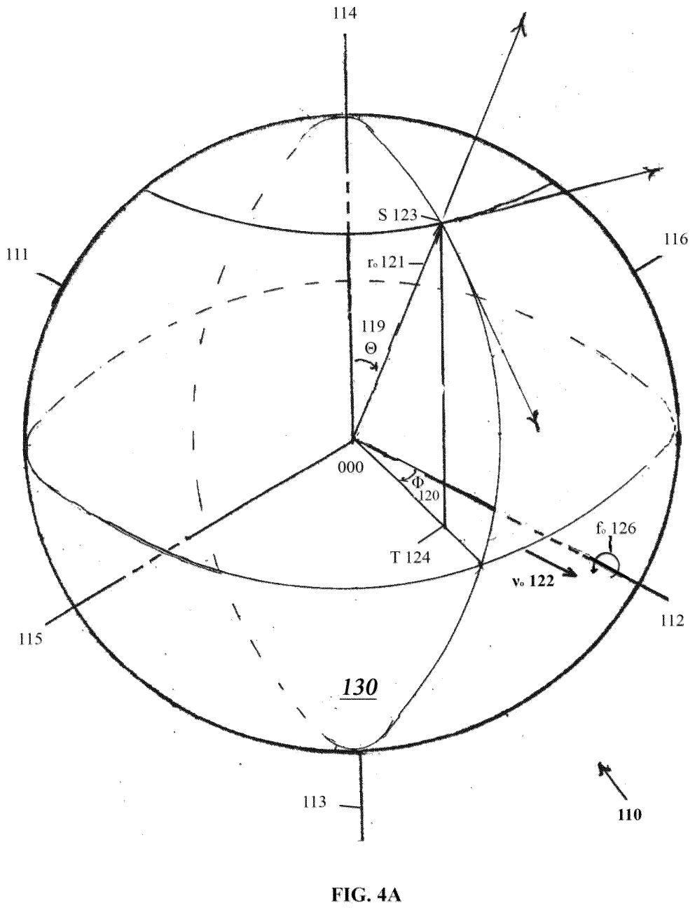

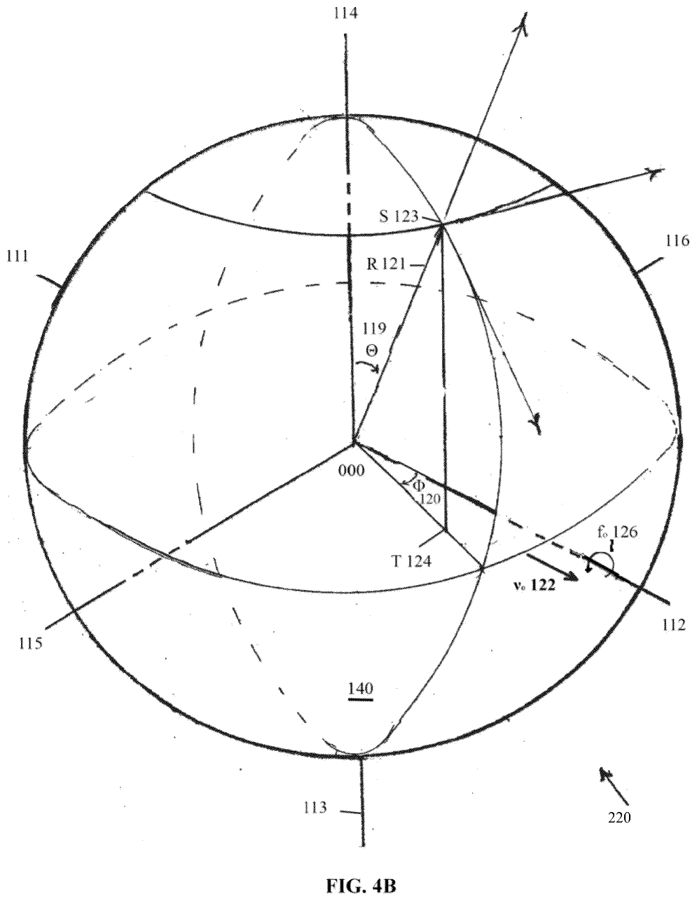

FIG. 4, shows an larger version (close-up) of the Sphere 130 from the Mathematical Universe 110 of FIG. 3, with a location vector R_{υ} from the center of the Spherical Coordinates System to the center of the Sphere; whereby the parameters (rₒ,θ,φ) are defined as follows: assuming an arbitrary point S 123 on the surface of the Sphere 130, then rₒ 121 is the distance from S 123 to the center of the Sphere; if one drops a vertical line from point S 123 that lands perpendicular to the xy plane (x identified as axis 111-112, y identified as axis 115-116), at point T 124, then the angle between the positive x-axis 112 and the line from the center to T 124 is φ 120; the angle between the positive z-axis 114 and the line segment from the center to point S 123 is θ 119. These spherical coordinates can locate any object in the 3-dimensional space of the Spherical Coordinates System formed by the x 111-112, y 115-116, and z 113-114 axis of the 3 orthogonal planes xy-plane, yz-plane and zx-plane. FIG. 4 shows positive axis x 112, y 116, and z 114 from 0 to +∞; and negative axis −x 111, −y 115, and −z 113 from 0 to −∞ for each axis respectively at 180° in the opposite direction. Moving from the Mathematical Universe 110 to the Real Universe 220 (see FIG. 4B and substituting radius R for rₒ and electron designation 140 for 130); however, the essential aspects of the Mathematical Universe 110 fully apply to the Real Universe 220.

### The Spinning Sphere and its Connection to the Electric Charge, Cosmic Microwave Background Radiation (CMBR), and Mass.

Given the sphere 130 (see FIG. 3) with volume V 107 and radius rₒ 121, the sphere 130 is in motion v. 122, spinning with a spin frequency fₒ 126, resulting in (V/T)i_{φ}, or the spherical volume V 107, (4/3) πR³, yields the above expression, which leads to certain laws in the universe; but these laws have never been able to unify two related scientific phenomena-gravity and electromagnetism. However, if one considers motion to be the ratio of volume to time, the ratio not only unifies gravity and electromagnetism with the motion of a Sphere's volume (i.e., or any 3-dimensional body) but also can improve understanding of current physics laws.

The expression mv indicates a moving mass m, and the expression q/t indicates a moving charge q. With volume V 107 (FIGS. 2, 3, and 4) common to both mass and charge, the volume's motion differs depending on Vᵥ, or V/T. Dimensional analysis yields L⁴/T for Vᵥ, and L³/T for V/T; where Lis length, and T is time.

All masses and all charges are volumes (i.e., 3 dimensional). Conventional Physics expresses motion as mu, which is 4-dimensional space (assuming mass is 3 dimensional); whereas motion V/t is a 3-dimensional space; (consult FIG. 4B, which contain spherical coordinates R, θ, and φ). Relativity occurs in the fourth dimensional space. There is no realistic object L⁴/T in motion, whereas all objects in motion are L³/T. The Applicants examination of the universe reveals that motion is V/t, and in the Detailed Description of the present invention we will show how the analysis unifies electromagnetism and gravity, given Newton's first two laws of motion, spherical coordinates, volume, velocity, acceleration, spin, rotation, space, and time.

In physics, using spherical coordinates (see FIG. 4B) at the equator, the radius R 121,

$$R ( {i}_{r} + {i}_{θ} + {i}_{φ} ) , \qquad ( 1 )$$

Where the sphere makes one revolution in time T. The spinning sphere has the mathematical expression:

$$[ ( 4 / 3 ) π {R}^{3} / T ] {i}_{φ} , thus \qquad ( 2 )$$

$$( V / T ) {i}_{φ} = [ ( 4 / 3 ) π {R}^{3} / T ] {i}_{φ} \qquad ( 3 )$$

but at the equator the spinning sphere has the constant spin speed, υₒ 122 of

$${υ}_{0} = 2 π R / T , \qquad ( 4 )$$

therefore a mathematical expression for the sphere's spin velocity υₒ 122 is

$$v = {υ}_{0} {i}_{φ} = 2 π {Ri}_{φ} / T . \qquad ( 5 )$$

Because the sphere has a spin velocity that changes direction every 2π/T of a revolution, the sphere's spin acceleration is

$$a = {υ}_{0} {i}_{φ} / T = 4 {π}^{2} {Ri}_{φ} / {T}^{2} , \qquad ( 6 )$$

yielding the sphere's spin equation

$$( 1 / 3 π ) {R}^{2} [ 4 {π}^{2} R / {T}^{2} ] = K ; \qquad ( 7 )$$

where K is a constant having the dimensional form

$${L}^{3} / {T}^{2} . \qquad ( 8 )$$

Rearranging terms, in the equation (7), and multiplying both sides of the equation by 3π yields

$${R}^{2} [ 4 {π}^{2} R / {T}^{2} ] = 3 π K , \qquad ( 9 )$$

yields

$${R}^{3} / {T}^{2} = ( 3 / 4 π ) K , \qquad ( 10 )$$

$$and$$

$${R}^{3} / {T}^{2} = {K}_{1} , \qquad ( 11 )$$

is Johannes Kepler's (1571-1630), third law of planetary motion.

At the equator, viewing the spinning sphere as V/T, generates Kepler's 3rd law of planetary motion, and posits that the spinning sphere is the basis of Kepler's empirical relationship R³/T²=K₁.

Kepler's R³/T²=K₁ works for every celestial body orbiting the Sun, works for particles in Saturn's rings, and works for every moon's orbit about their respective planet. Note that electrons are moving bodies and therefore they spin; as such they also follow Kepler's 3^{rd} law of planetary motion. The implications of this statement will become apparent when we discuss the details of the structure of the Atom.

The purely space-time mathematical relationship, R³/T²=K₁, is telling every particle in our solar system how to move. The spinning sphere, R³/T²=K₁, is the Sun, which is the matter, telling every point in space, to move according to the spacetime relationship R³/T²=K₁, which is the only movement the Sun is transmitting to the universe, while it carries all its objects and space as the Sun orbits another star. Similar to the Earth carrying its Moon, artificial satellites and space, as the Earth orbits the Sun. All solar system objects follow R³/T²=K₁, Kepler's third law of planetary motion.

Issac Newton (1643-1726) derived R³/T²=K₁ from his universal gravitational equation, F=GMm/R², but the two equations differ in space-time. In Kepler's solar universe, a point orbits the Sun with an acceleration along the orbital path in accordance with R³/T²=K₁, or α=(3πK₁/R²)i_{φ}, but in Newton's solar universe he has every point radially accelerating with a magnitude a=(GMm/R²)iᵣ, to the Sun's center. The two accelerations (3πK₁/R²)i_{φ}, and (GMm/R²)iᵣ, are orthogonal, and cannot be equal. They may have equal magnitudes, but they are not equal. The two directions i_{φ} and iᵣ are different.

Given the astronomical stability of planet's orbit, the stability of Saturn's orbital rings, and the stability of moons' orbit about their respective planets, there is no astronomical visual evidence that every point in celestial space is accelerating with a magnitude α=(GMm/R²)i, towards the Sun's center, but there is astronomical evidence that the orbital acceleration a=(3πK₁/R²)i_{φ}, is curving space-time about the Sun.

### Mass:

The spinning sphere is (V/T)i_{φ}, or (2/3)R²(2πR/T)i_{φ}. The correct spin speed magnitude varies as θ 19 (FIG. 4B) varies from 0 degrees at the north pole, to 90 degrees at the equator, and 180 degrees at the south pole. The sphere's spin velocity equation is

$$v = ( 2 πR / T ) sin θ {i}_{φ} , \qquad ( 12 )$$

the equation for acceleration is

$$a = ( 2 π R / {T}^{2} ) sin θ {i}_{φ} , \qquad ( 13 )$$

and the equation for force is

$$F = F {i}_{φ} . \qquad ( 14 )$$

The velocity equation, v=(2πR/T) sin θi_{φ}, has maximal spin speed at the equator, and zero spin speed at the poles, creating an increasing velocity gradient from the poles to the equator. Given the Earth's age of 4.5 billion years, the latitudinal velocity gradient requires an almost infinite stress modulus of elasticity to prevent the Earth from breaking up into many latitudinal discs. No material has an almost infinite stress modulus of elasticity, and all ocean waters are not at the equator.

Every latitude having the same velocity obviates the velocity gradient, therefore the zero-velocity gradient alters external time relationship with the object's internal time. Of course, the circumference is 2πR sin θ, but the time is not the observer's time T, but rather the object's time (sin θ)T yielding the constant velocity. The observer adds the fourth dimension, just as the velocity, υ adds the fourth dimension to the mass movement in mu, but as far as the moving object is concerned both observer and external velocities are irrelevant to the object's motion, therefore

$$2 π R sin θ = υ T sin θ . \qquad ( 15 )$$

Similarly, every latitude has the same acceleration, therefore the space time relationship is

$$2 π R sin θ = {aT}^{2} sin θ , \qquad ( 16 )$$

and every latitude has the same spin force. The sphere's internal time, tᵢ=T sin θ, and experimental external time, tₑ=T, are independent, and seems to uphold Newton's absolute time concept of the object's time being independent from the external time.
There is a constant force F=F i_{φ}, and there is an acceleration
(2πR sin θ/(T² sin θ))i_{φ}, therefore there is a mass

$$m = F {i}_{φ} / ( 2 π R sin θ / ( {T}^{2} sin θ ) ) {i}_{φ} = {FT}^{2} / ( 2 π R ) \qquad ( 17 )$$

concluding that spin creates mass, that an orbit creates mass, that a sinusoid creates mass, that vibration creates mass, and that any change in the motion of a body creates mass.

Proof: Issac Newton's first law of motion: every object remains at rest, or in uniform motion in a straight line, unless the object is compelled to alter its course by the action of an external force, since a spinning object is changing its direction, then a spin force is changing the direction. A spinning object has a spinning velocity that changes direction, a definition of acceleration, and the acceleration's direction has the same spin force's direction.

Through Newton's second law of motion, F=ma, the spinning sphere creates mass

$$m = F / a , \qquad ( 18 )$$

which is a mass creation mechanism altering the Standard Model. With the exception of Higgs bosom, the Standard Model has all spin particles, therefore all Standard Model particles have mass.

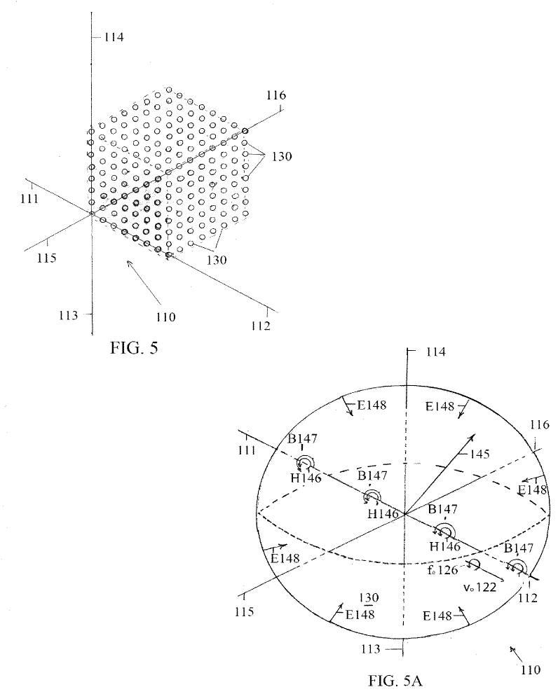

### Cosmic Microwave Background Radiation (CMBR; see FIGS. 4B and 5)

In the circular i_{φ}, direction, a spherical mass has a circular force Fi_{φ}, acting along the circumferential distance 2πR sin θi_{φ}, to create the energy Fi_{φ} 2πR sin θi_{φ}, and states there is more energy, heat, at the equator than at the poles, but the crucial aspect is that spin creates heat, and spin is a factor in the cosmic microwave background radiation's temperature of 2.725 K. The energy is the dot product of force, Fi_{φ} and distance, 2πR sin θi_{φ}.

The Earth's spin has been creating energy for 4.5 billion years, the photon's spin has been around for longer than 4.5 billion years, and because it has been shown that spin creates heat, creates mass, and creates motion, the Applicants assert that these facts demonstrates that perpetual energy is a reality.

Thus far, analysis using the ratio V/t yields the equation (4/3)πR³/T²=K, which is consistent with the format of Kepler's empirical third law of planetary motion, R³/T²=K₁, and is the space-time equation telling our solar system universe how to move, has time proportional to length, has the object's internal time independent from the object's external time, creates mass, questions the Standard Model's zero mass particles, and creates heat.

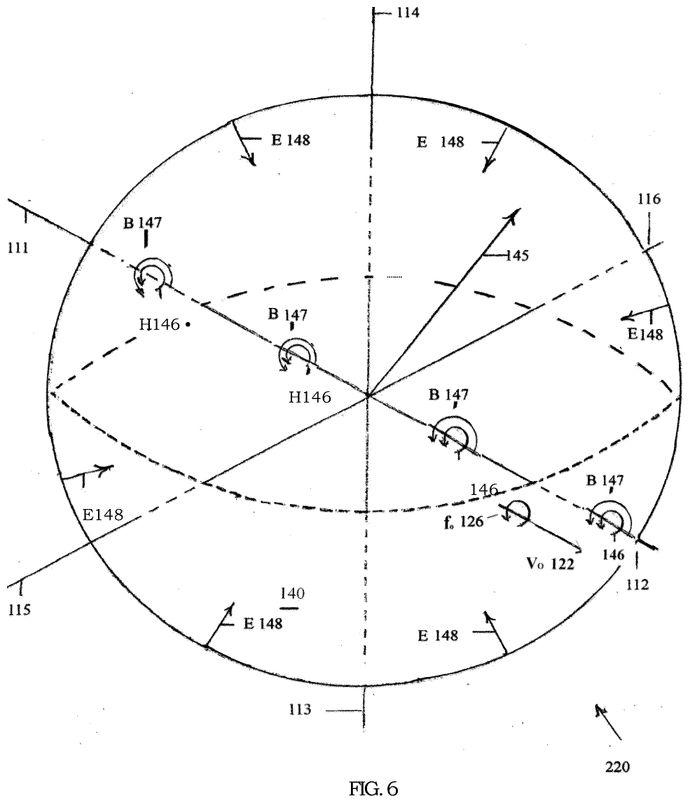

The Magnetic Vector B 147 and The Electric Vector E 148 (see FIG. 6): The motion of the volume of the spinning sphere results in the vector (4/3)πr²υₒ i_{φ} (see FIG. 6). Said vector and the static sphere vectors (r/2)(iᵣ) and (r/2)(i_{θ}) which equals r(iᵣ+i_{θ})/2 are positive. On and in the sphere, these two simultaneous vectors interact. One mathematical vector interaction is the cross product.

$$( 4 / 3 ) π {r}^{2} {υ}_{o} {i}_{φ} \times r ( {i}_{r} + {r}_{θ} ) / 2 = ( 2 / 3 ) π {r}^{2} {υ}_{o} {i}_{r} ( - {i}_{r} + {i}_{θ} ) . \qquad ( 19 )$$

Because motion encounters cross sectional area resistance, πr² and velocity square resistance, υₒ², the spinning sphere has the resultant magnetic vector B 147 (FIG. 6)

$$B = ( 2 / 3 ) {μ}_{o} ( r / {υ}_{o} ) ( - {i}_{r} + {i}_{θ} ) , \qquad ( 20 )$$

which is a torque causing the sphere to spin in the υₒri_{θ} direction, and a vector υₒr(−iᵣ) attracting everything within the sphere to the sphere's center. This constant velocity υₒl_{φ} causes the sphere to spin with velocity υₒi_{θ}, and along the radial direction, causes every point to move with velocity vₒiᵣ, to the sphere's center.

The sphere's spin, υₒi_{φ}, creates motion along the i_{θ} spin direction, and creates motion along the radial direction, iᵣ, towards the sphere's center. In any given motion direction, the vector cross product distributes part of its motion to the other two remaining orthogonal directions. With energy in the direction of motion, there is no energy given to the two remaining orthogonal directions. The vector cross product is a mathematical operation creating motion orthogonal to the motion direction. Every motion has this cross product.

The spinning sphere (FIG. 6A) has vectors υₒi_{φ}, and vector B 147. The cross product produces the vector E 148.

$${υ}_{o} {i}_{φ} \times B = E = {υ}_{o} {i}_{φ} \times ( 2 / 3 ) ( r / {υ}_{o} ) ( - {i}_{r} + {i}_{θ} ) = ( 2 / 3 ) ( r ) ( - {i}_{r} - {i}_{θ} ) , \qquad ( 21 )$$

distributes time, and changes i_{θ}'s spin direction.

There is another velocity vector. The sphere is (2/3)πr²υ₀(−iᵣ+i_{θ}), which crosses with the static vector ri_{φ}/2 to yield

$$( 2 / 3 ) π {r}^{2} {v}_{0} ( - {i}_{r} + {i}_{θ} ) \times {ri}_{φ} / 2 = ( 1 / 3 ) π {r}^{2} {υ}_{0} ( {i}_{r} + {i}_{θ} ) \qquad ( 22 )$$

and divide by πr²υ₀² yields

$${B}_{1} = ( 1 / 3 ) ( r / {υ}_{o} ) ( {i}_{r} + {i}_{θ} ) . \qquad ( 23 )$$

The cross product of

$${υ}_{o} ( - {i}_{r} + {i}_{θ} ) \times {B}_{1} = {v}_{o} ( - {i}_{r} + {i}_{θ} ) \times ( 1 / 3 ) ( r / {υ}_{o} ) ( {i}_{r} + {i}_{θ} ) = - ( 2 / 3 ) {ri}_{φ} , \qquad ( 24 )$$

yields

$${E}_{1} = - ( 2 / 3 ) {ri}_{φ} , \qquad ( 25 )$$

and creates a spin direction opposite to the initial spin direction. The sum of these E vectors is

$${E}_{t} = E + {E}_{1} = ( 2 / 3 ) ( r ) ( - {i}_{r} - {i}_{θ} - {i}_{φ} ) , \qquad ( 26 )$$

which is a vector attracting everything to the spherical center. This is a spinning sphere, it is not a charge, but radial vector lines normal to the spherical surface pointing to the spherical center. The Applicants assert that it represents both a negative charge and gravity. All photons spin, therefore, photons have mass, are negative charges, and have a gravity vector. The spinning sphere creates a mass, creates a negative charge, and creates a vector attracting everything to the spherical center, and this attracting vector is gravity. The spinning sphere unifies gravity, electricity, magnetism, and light. It follows that F=GMm/R², F=q₁q₂/(4πϵₒr²), and light intensity α 1/r² have the same form because the vectors come from one source, the spinning sphere. The cross product creates the electromagnetic vectors, and the gravity vector.

The spinning sphere 140 (see FIG. 6) through vector cross products creates a magnetic vector B 147, an electric vector E 148, and a charge q (not in diagram). The electric vector E=−v×B, is normal to the spherical surface, therefore the divergence is not zero. The magnetic vector B=v×E/v², is rotational (about the direction of travel axis 112), therefore has a zero divergence. These equations constitute Maxwell's electromagnetic laws. E=q/(4πεₒr²).

Finally, as shown in FIGS. 4 and 4A, the Sphere with radius rₒ 121, orbital speed υₒ 122, orbiting a central point 000 at a radial distance from its center R 117, has the cross product

$$( 4 / 3 ) π {r}_{o}^{2} ( - {υ}_{0} ) {i}_{φ} , \times R ( - {i}_{r} - {i}_{θ} ) / 2 = ( 2 / 3 ) π {r}_{o}^{2} ( {υ}_{o} ) R ( - {i}_{r} + {i}_{θ} ) , \qquad ( 27 )$$

and dividing by πₒ²υ₀² yields (see FIG. 6)

$$B = ( 2 / 3 ) ( R / {υ}_{0} ) ( - {i}_{r} + {i}_{θ} ) . \qquad ( 28 )$$

The cross product

$$E = v \times B = ( - {υ}_{o} ) {i}_{υ} , \times ( 2 / 3 ) ( R / {υ}_{0} ) ( - {i}_{r} + {i}_{θ} ) = ( 2 / 3 ) R ( {i}_{r} + {i}_{θ} ) , \qquad ( 29 )$$

The sphere and velocity is (2/3)πrₒ²υ₀(−iᵣ+i_{θ}) and crosses with (−R)i_{φ}/2 to yield

$$( 1 / 3 ) {π}_{ro}^{2} {υ}_{o} R ( - {i}_{r} - {i}_{θ} ) , \qquad ( 30 )$$

$${B}_{1} = ( 1 / 3 ) ( R / {υ}_{o} ) ( - {i}_{r} - {i}_{θ} ) , \qquad ( 31 )$$

The cross product

$$= v \times {B}_{1} = {υ}_{o} ( - {i}_{r} + {i}_{θ} ) \times ( 1 / 3 ) ( R / {υ}_{o} ) ( - {i}_{r} - {i}_{θ} ) = ( 2 / 3 ) {Ri}_{φ} \qquad ( 32 )$$

which is a vector pointing outwardly from 000, pushing against the center of the orbiting sphere and away from the central point 000, thus creating a centrifugal vector.

The sum

$$E + {E}_{1} = ( 2 / 3 ) R ( {i}_{r} + {i}_{θ} + {i}_{φ} ) , \qquad ( 33 )$$

The Electric Charge, Cosmic Microwave Background Radiation (CMBR), and Mass: A sphere in motion has a motion vector which interacts with the sphere's vector points, which are Euclid points (that which has no parts) to create a real torque that spins the sphere consistent with the right hand rule; thus, sparking the Equivalence Corollary to Newton's First Law of Motion whereby the Corollary states that a body in motion (e.g., a sphere) will spin about the axis of motion and will continue to spin unless it is acted upon by an external force to stop or alter the rotation. According to Newton, a body in rectilinear motion has no force acting on it; but the interaction of the vectors causes the sphere to spin about the direction of motion, creating a torque which is a force. Thus we have created a torque (force) out of the interaction of motion with Euclid's points. The spinning Sphere 140 in turn creates a magnetic field intensity vector H 146 (see FIG. 6). Hence anything that moves has this torque (Spin fₒ 126) or H 146, and B 147, and E 148 vectors (fields).

Stepping from the Mathematical Universe 110 back into the Real Universe, we find that the ocean of negatively charged mathematical points 130 in the Mathematical Universe (see FIGS. 4A and 5) have attributes that coincide with those of the photon in the Real Universe 220 because photons are three-dimensional solid particles, and if all the photons are of the same size and have the same speed υ_{O} 122 and spin fₒ 126 then all photons have the same charges and are equal, thus the real universe is filled with them. Now when the Photons collide at right angles, they form triangular waves of photons which forms the cosmic microwave background radiation (CMBR). These are right triangular waves, each side having a length of 1.37 mm and hypotonus of 1.94 mm; which is also the wavelength. Photon collision causes an increase or decrease in the photon vibrational frequency. These negative particles 130 are represented in the Mathematical Universe 110 of FIG. 5, as the equivalent of the Photons in the CMBR in the Real Universe 220. Furthermore when photons as discussed above, moving in triangular waves collide, they create a specific frequency and a specific wavelength standing wave, in each of the pairs of the three orthogonal axes; the specific frequency standing wave in each of the orthogonal axes, taken two at a time, creates an electron with the spin frequency of the standing wave's specific frequency, and constant spin speed υₒ. Photon's moving in the remaining two pairs of orthogonal axes similarly follow the same process to create electrons. In this way, Photons collide at infinitum, thus creating an endless number of electrons; with spin frequency distribution from extremely high to very infrequent; that is ranging from fₑ to fₑ/α³ with corresponding wavelengths, producing electrons of various sizes and masses to populate and maintained the pool of electrons which can be drawn on to make the wide range of Elements known to modern science today. In subsequent paragraphs we will show (see FIG. 5A) how this mathematical equivalent of a Photon exhibits E, B, and H vectors like Real Universe 220 Photons.

The Derivation of Mass and Heat: the mathematical point 130 (a sphere, see FIG. 4A moves with a constant speed v. 122, and whenever anything moves it means there is a constant force acting on the sphere (using the Right hand rule with thumb pointing in the direction the sphere is traveling, the fingers are curled in the direction of a torquing force, causing the sphere to spin, and because there is a change in direction, there is an acceleration along the direction of spin. Given that F=ma, therefore

$$m = \frac{F}{a} ,$$

which leads to another way to derive mass!!! Again, note that this approach is a lot deeper than that, because spinning any object creates mass. Also note that both charge and mass have been derived from spinning Sphere 130

The mathematical point 130 (see FIG. 4A, a spinning sphere) has an equator and poles and a constant force spinning the sphere. The maximal circle spinning about the pole axis is the equatorial circle 2πrₒ and this circle becomes zero at the poles. Work is force times distance, hence more work is done at the equator than at the poles, therefore there is more heat at the equator than at the poles! The poles are cold, and the equator is hot. But again, without any energy from the external environment of this spinning mathematical point 130, this line of reasoning leads to another way to derive heat!!! Now the Mathematical Universe is complete, with charge, mass, and heat. One moving mathematical point 130 is the genesis of the mathematical universe. Keep in mind that the mathematical universe is the interaction of space and time, and this is all that exists, space and time, from which charge, mass, and heat are derived. Given this analysis and using the mathematical universe as a staging area, the derivation of charge, heat, and mass, it will be easier to model electrons, atoms, elements, molecules, compounds, and any other atomic structures.

As you can see the significance of this line of reasoning is enormous, but a few more steps prior to creating electrons. There is the principle of displacement, and oddly enough it goes back to Archimedes dealing with objects in a fluid. An obvious principle: in a fluid, an immersed object has the same volume as the fluid's displaced volume. Tossing a stone into a pond generates a series of increasing discrete radius concentric circles, with decreasing discrete heights as the discrete radius increases. This is an incredible universal observation. Ask yourself what do these discrete radii and heights represent? It is only one thing these circles and heights can only represent the stone's volume. So, the equation hπr²=V; where h is a very complex height representation, r is the radius of the concentric circles, and V is the stone's volume. Let hₙ equal the height of the nth wave and nr is the radius of the nth wave; then the equation

$${h}_{n} = \frac{V}{{π ( nr )}^{2}}$$

is the inverse square distance that you see in a charge, is the inverse square distance that you see in the light intensity and is the inverse square distance that you see in the discrete wavelength making up the atom's spectral lines in quantum mechanics and is the inverse square law that you see in gravity. Who could have guessed that tossing a stone into a pond explains all these universal observations?

Impact of Collision on Energy, Mass, Frequency and Temperature: The next important and final principle is collision and that is all that these mathematical points can do—they can collide, which post collision causes the sphere to vibrate radially. For example, along the x-axis, two opposite traveling spheres collide causing both sphere's surfaces to vibrate radially in each sphere's iᵣ direction, as each sphere travels in opposite direction along the x axis. Post collision there is a certain spherical displacement, and an increase in the frequency amount, such that λf=v where λ a displacement amount, f is the frequency, and v is the constant vibrational speed, which is the same speed that the object is moving.

Now if an electromagnetic wave has a frequency f what is the wavelength? The underlying understanding is that the wave is traveling at the speed of light and the ratio c/f quickly answered that question. No matter the frequency, you always came up with the answer, given the constant speed of light and given the constant speed. Is this any different from the rotating Earth, where from the equator to the poles, the different circumferences are the wavelengths, and the different times are the different frequencies? It turns out that these displacements and frequencies are harmonics because they follow the harmonic series λ(1+1/2+1/3 . . . +1/n), but since the speed of these vibrations must be v, then the representation of this moving back and forth displacement is (λ/n)sin 2πnft and the speed of this displacement is (λ/n)nf sin 2πnft; i.e., the displacement is reduced by the discrete integer n as in (λ/n), and the frequency is increased by the same discrete integer n as in (nf). This equation is true for any vibrating body. Now inspecting these vibrations, we note that the vibrations occur sequentially, and not simultaneously. The sphere, which can never be created or destroyed, is the only constant in this process. Since the vibration is along the sphere's radial direction, therefore it is a vector acting on and in the sphere.

The post collision sequence starts with the sphere moving a distance λₑ and then the harmonic series starts, i.e., 1+1/2+1/3+ . . . +1/n The sphere has moved a distance λₑ, and has the wavelength λₑ, when the first harmonic appears (1) and the sphere has wavelength (λₑ), form the product (1)(λₑ), to add to the total sphere's travel distance or λₑ, +(1)(λₑ) and imparts the wavelength (1)(λₑ), to the sphere.

The next sequential harmonic (1/2) forms the product with the spheres wavelength product (1)(λₑ) to yield the product (1/2)(1)(λₑ) to move the sphere by this product distance, λₑ, +(1)(λₑ)+(1/2)(1)(λₑ), and imparts the sphere with the wavelength product (1/2)(1)(λₑ).

The next sequential harmonic (1/3) forms the product with the sphere's wavelength product (1)(1/2)(λₑ) to yield the product (1)(1/2)(1/3)(λₑ) to move the sphere by this product distance, (1)(1/2)(1/3)(λₑ) for a total distance λₑ, +(1)(λₑ)+(1)(1/2)(λₑ)+(1)(1/2)(1/3)(λₑ), imparts the sphere with the wavelength product ((1)(1/2)(1/3)(λₑ).

The nth harmonic series term (1/n) forms the product with the sphere's wavelength product (1)(1/2)(1/3) . . . (1/(n−1))(λₑ) to yield the product ((1)(1/2)(1/3) . . . (1/(n−1))(1/n)(λₑ) to move the sphere by this product distance, λₑ(1)(1/2)(1/3) . . . (1/(n−1)!)(1/n!) for a total distance λₑ, (1+(1)+(1)(1/2)+(1)(1/2)(1/3)+ . . . +1/(n−1)!, +1/ni) imparts the sphere with the wavelength product λₑ(1)(1/2)(1/3) . . . (1/(n−1)!)(1/n!).

The distance traveled is in

$${λ}_{e} [ 1 + \frac{1}{1 !} + \frac{1}{2 !} + \frac{1}{3 !} + … + \frac{1}{n !} + … ] .$$

The results is that

$$[ 1 + \frac{1}{1 !} + \frac{1}{2 !} + \frac{1}{3 !} + … + \frac{1}{n !} + … ]$$

is the natural number e. Yes, that same e that exist in the LRC circuits, and it comes about, due to the consequence of two mathematical points colliding.

The sphere is vibrating back-and-forth, and for this back-and-forth movement to occur, the direction must change, but a change in direction is an acceleration, and since the sphere has mass, we have just created a force, which only acts during this directional change, or the force acts during these discrete incremental changes, then the work done is force times distance, which is heat. So, these vibrations cause the sphere to experience heat, or cause the sphere to have a temperature. Recall that we are saying that the mathematical point in nature is the photon, and physics experimentally finds that these photons are at an absolute temperature of 2.725 degrees Kelvin, which may very well be e's value 2.71828183 plus the heat production from spinning sphere. These photon collisions and associated spin can account for the past, present and future universal heat without fearing a universe going to absolute zero.

a Key Take-Away from the Above Collision Discussion is that:
A colliding body can result in an increase in mass, an increase in frequency and an increase in temperature.
For example, continuing with the analogy that the mathematical point in nature is the photon, then the absolute temperature of space (at 2.725 Kelvin) can be attributed to the temperature increase caused by the constant collisions of the photons in the real universe and their resultant spin.

Equivalence of Energy, Mass, Frequency, and Temperature: while we are on heat let's look at three energy equations in physics: E=mc², E=hf, and E=kT; where E is energy, m is mass, c is the speed of light, h is Planck's constant, f is frequency, k is Boltzmann's constant, and T is absolute temperature. You are aware of the most famous equation in physics E=mc², which says that there is an equivalence between Energy and mass because c² is a constant. Einstein certainly showed a great deal of insight.

Let us look at E=hf hardly anyone knows this equation, and you will not find E=hf written on any mural. Einstein came up with E=hf, and in fact, was the equation that got him the Nobel Prize in 1921, yet not too many people know about it. What does E=hf say? It says that energy is equal to the product of Planck's constant and frequency, and by the same reasoning process as in E=mc² that concludes, and we accept that mass is equivalent to energy, then we must conclude that frequency is equivalent to energy! For example, the energy that a spinning top has is equivalent to the top's spin frequency because a vibration involves a frequency of going back and forth and that this energy is equivalent to that back-and-forth frequency, and finally that whenever there is a frequency, there is energy. The hands of the clock moving around in a circle is energy, the pendulum moving back and forth is energy, the Earth orbiting the Sun is energy, the Earth spinning on its axis is energy, the electron spinning on its axis is energy, and it goes on and on, but note that E=mc² is more famous than E=hf despite the fact that we have no concept of mass, and a very clear concept of frequency. The culmination of all of this: mass and frequency are equivalent! Recall that from an earlier discussion we created mass from a spinning sphere, and through these two equations E=mc² and E=hf. Not only does the spinning Earth create mass, but the orbiting Earth also creates mass, the clock's hand create mass, the tides create mass, movement creates mass and the plucking of a violin string, striking a note on a piano key, and playing the guitar creates mass. Do you now see that we really do not know what mass is?

Let us look at E=kT and the same reasoning concludes that energy and absolute temperature are equivalent, but it does not stop there, because absolute temperature is equivalent to mass, and as that absolute temperature of an object increases, the mass increases either by causing more collisions or making the object spin faster. Absolute temperature is equivalent to frequency the greater the temperature the faster the spin, or the more collisions.

So, what is the big deal with E=hf. Look at what it states: it says that frequency and energy are equivalent and notice that it does not mention anything about size; all E=hf says is that if a big sphere or a huge object shakes or rotates at a frequency f, the energy in that sphere or object is the same as the energy in a microscopic sphere shaking or spinning with the same frequency f! When we set E=mc²=E=hf, or m=(h/c²)f, the mass becomes infinite with infinite frequency, which can almost take place in a microscopic or quantum sphere. Go over that again, a microscopic sphere spinning fast enough can have the mass of the Sun! But here is the flash E=hf=E=kT, or T=(h/k)f, and yes that same frequency causing that microscopic sphere to have the mass of the Sun is now causing the high temperatures of the Sun! This equation E=hf creates mass and temperature by simply having a spinning frequency. Think about this the Sun is said to have its temperature as the result of atomic nuclear reactions, and that sooner, or later, there is going to be a depletion of the reactants. A gloomy picture for the Earth but recall that the mathematical point can neither be created or destroyed, and if the photon is the mathematical point, which is always in motion, then the spin is perpetual, which concludes that the microscopic spinning sphere spins forever, and the temperature will last forever! The universe, the Earth, the Solar system is here to stay. Sure, there can be a catastrophe, but barring a catastrophe the Earth will go on. Democritus is indeed a genius who utilized the power of reasoning to reason the correct makeup of the universe. Every celestial body is a spinning quantum sphere, every celestial body has mass and a temperature, and all is due to E=mc²=hf=kT. Simply incredible and quite simple, by the same reasoning power, every atom must be created from these mathematical points, or photons.

Key take-aways from the above Equivalence discussion and Collision discussion before that is:
A rotating body can increase mass;
A spinning body can increase mass;
A colliding body can increase mass.

The Physics of the Equivalence of Mass, Frequency, and Temperature to Energy fosters a natural affinity to use only electrons as the basic building blocks to structure each element's atom.

The Fine Structure Constant α=1/137: before we create an electron let's look at two facts because these mathematical points are moving with constant speed v, and spin with speed vₒ. We have established that the mathematical point has mass and charge, hence the points offer a resistance to each other, so that if there were only one point in the universe its speed would certainly be different than if there were several points in a given volume of space, and with a greater number of points per volume of space, the slower the point would move. Since we are thinking that the photon is the mathematical point let us give the mathematical point an extremely high speed vₒ. The mathematical point is a sphere, and the sphere must go thru this resistance, which is a function of the number of points in a defined 3-dimensional space and call this p. Since the attribute of the point is its volume, then the ratio of the point's volume to the volume of a defined 3-dimensional space is dimensionless. Let us take 389 mathematical points in a cubic centimeter. It has been calculated that about 400 photons per cubic cm, so we are not far off from the photon number in a cubic cm. The cross-sectional area of the sphere is a resistance to the mathematical point's motion. The shape and speed of the moving object also is a resistance to its motion, and is a dimensionless number with a value ≈C_{d}, for a sphere asymptotic approaching a maximum value of 0.47 at an infinite speed, hence the speed of the mathematical point

$${v}_{o} = [ ( 4 / 3 ) π {r}_{o}^{2} / ( {πr}_{o}^{2} ρ {C}_{d} ] c$$

where c is the speed of the mathematical point in a total vacuum, yielding vₒ=c/137.122500. What if we make this exactly 137, then at C_{d}=0.469580120 the speed is close to vₒ and vₒ=c/137. The prime number 137 appears to be ubiquitous in the atomic structure and the inverse of 137 is called the fine structure constant, α.

The Inventors' mathematical point gets to a remarkably close approximation to the Fine Structure Constant α=1/137, but it does not stop there. The number of mathematical points in a cubic cm is the prime number 389, which has 389^{1/3}=7.29989366 mathematical points on its 1 cm edge, with a distance between points of 0.136988297 cm between mathematical points. let us define the distance between mathematical points as 0.137 cm exactly. Look how close we are to the defined cm 0.137 versus 0.136988297 or off by about 0.000017031432. quite close indeed. Now we come to one of the most challenging aspects in the real universe, but it should not be a challenge in the mathematical universe. The mathematical universe has an aether because the mathematical point is a negative charge and creates a matrix where every charge is 0.137 cm from its six adjacent neighbors. So, the sea of the mathematical universe is homogeneously spaced moving mathematical points.

Key Take-Aways from the Fine Structure Constant Discussion is that (See FIG. 5):
The mathematical Universe consists of homogeneously spaced moving mathematical points;
The mathematical point is negatively charged (see FIGS. 5 and 5A) and creates a matrix where every charge (point) is 0.137 cm from its six adjacent neighbors; and between adjacent neighbors there are an infinite number of continuous Euclid vector points. Therefore, the space between the mathematical points is the eather. These mathematical points along with the space between them is the CMBR in the Real Universe 220 (see FIG. 6).
The mathematical point gets to a remarkably close approximation to the Fine Structure Constant α=1/137; said Fine Structure Constant, α plays a pivotal role in how each element's atom is structured using only electrons.
There is a problem saying that the mathematical points are the aether because there is a 1.37 mm space between them. The aether is the continuous vector points. This seems strange because the vector points are not real, but they are space points; i.e. recall that the position vectors define every space location. It is these continuous space vectors creating the sphere's lengths along a given direction. Now it seems more understandable when the photon is a solid sphere, having a radius much smaller than the electron, that the volume between photons is a spherical shell and the space from the sphere's center to the inner shell is in fact a true volume, so then the space vector locators are the continuous space vectors becoming the fulcrum rotating the sphere. The vector point is the Euclidian point “that which has no parts”, and in essence, becomes the ideal aether because the inner moving photon encounters no aether resistance. The aether moves at the same exact speed, acceleration, and rotation as the photon moves.

The Relationship Between B, E, and v: one more digression before we get to the electron creation. The relationship (see Mathematical Point 130—FIG. 5A in the Mathematical Universe 110, and Photon 140—FIG. 6 in the Real Universe 220) between Magnetic vector B 147, E 148, and v is that B=−v×E/c² and Electric vector E=v×B. According to Lorentz, the force on a charge q is F=q[E+v×B], but B=−v×E/c², therefore F=qE[1−v²/c²], or there is an F/q=Eₜ=E[1−v²/c²]. Here are the three cases:

The Importance of the Equation: F/q=Eₜ=Eₜ=E[1−v²/c²]
When v is less than c, the electric vector, Eₜ is the same polarity as E.
When v is equal to c, the electric vector, Eₜ is zero irrespective of E.
When v is greater than c, the electric vector, Eₜ is the opposite polarity of E.
To make an electron, the sphere's spin speed must be less than c.
To make the neutron, the sphere's spin speed must be c.
To make a proton, the sphere's spin speed must be greater than c.

There is no need to make three separate distinct particles; the spin speed takes care of the polarity and magnitude of the charge. Also note that three particles have the same composition-a spinning sphere, and no quarks. Before leaving this most interesting section, the equations B=−v×E/c² and E=v×B are telling us something, and yes conceptually the cross product of B×E=v, thus telling us that the entire universe just needs the three orthogonal vectors B 147, E 148, and v.

As you can see if everything is going to come from these mathematical points, then there is nothing in the mathematical universe smaller than these points. Correspondingly, Photons become the smallest particles in the real universe. Now we are set to make an electron.

The Making of an Electron: Now that we have built a foundation using the facts supporting the basis of the new Atomic Model, we can use it to outline the detail structure of the first embodiment of the present invention, the new Atomic Model of the Atom, Electron, Molecule, Compound, and other atomic Structures of the Physical Universe.

Let us go to negative infinity and we have the mathematical point (2/3)υₒiₓ, while at positive infinity we have the mathematical point −(2/3)υₒiₓ. Eventually these two points collide, and post collision each point vibrates and creates the equation formed by the cross product of

$$[ ( \frac{2}{3} ) {v}_{o} {i}_{x} ]$$

by

$$[ {\sum }_{n = 1}^{n} ( {λ}_{e} / n ) {nf}_{e} cos ( 2 π {nf}_{e} t ) {i}_{r} ]$$

which, post collision, is the mathematical point (2/3)υₒiₓ, which was the pre collision mathematical point, −(2/3)υₒiₓ, and the mathematical point (2/3)υₒiₓ is moving along the positive x-axis, but now vibrating along ±iᵣ-axis due to the cosine function, and the vibration with the constant vibrational speed λₑfₑ=vₒ.

The cross product

$$[ ( \frac{2}{3} ) {v}_{o} {i}_{x} ]$$

by

$$[ {\sum }_{n = 1}^{n} ( {λ}_{e} / n ) {nf}_{e} cos ( 2 π {nf}_{e} t ) {i}_{x} ]$$

expression describes exactly the path the mathematical point is taking, but as this point continues to travel along the positive x-axis at distance L=0.137 cm collides with another mathematical point moving in the negative x-axis direction causing a post collision

$$[ - ( \frac{2}{3} ) {v}_{o} {i}_{x} ] [ {\sum }_{n = 1}^{n} ( {λ}_{e} / n ) {nf}_{e} cos ( 2 π {nf}_{e} t ) {i}_{x} ]$$

movement in the negative x-axis direction, and when this mathematical point travels the negative distance 0.137 cm, the mathematical point collides with a positive x-axis direction moving mathematical point. This ad infinitum occurring collisions creates the standing wave, which is nothing more than the mathematical point going back and forth the distance 0.137 cm.

Similarly, on the y-axis the function is

$$[ ( 2 / 3 ) {v}_{o} {i}_{y} ] [ {\sum }_{n = 1}^{n} ( {λ}_{e} / n ) {nf}_{e} sin ( 2 π {nf}_{e} t ) {i}_{y} ] .$$

Let us make note of what is going on. The first is that the equation is only one mathematical point and not an infinite number of mathematical points, because the sinusoidal, although an infinite number, occur sequentially i.e., when n=1 occurs, it lasts for a certain amount of time and distance, but when n=2 occurs, n=1 is gone, again when n=3 occurs, n=2 is gone. This process goes on ad infinitum. Just prior to the next collision, n is at its higher value.

Since the mathematical point is a sphere and has a wavelength λₑ, where the relationship 2πrₑ=λₑ, the equations become:

$$[ ( 2 / 3 ) {v}_{o} {i}_{x} ] [ {\sum }_{n = 1}^{n} ( 2 π {r}_{e} / n ) {nf}_{e} cos ( 2 π {nf}_{e} t ) {i}_{x} ] \\ and \\ [ ( 2 / 3 ) {v}_{o} {i}_{y} ] [ {\sum }_{n = 1}^{n} ( 2 π {r}_{e} / n ) {nf}_{e} cos ( 2 π {nf}_{e} t ) {i}_{y} ] .$$

These two equations represent 2 mathematical points.

The mathematical point going back and forth on the x-axis is spinning about the x-axis and causes the mathematical point going back and forth on the y-axis to go orbit the point on the x-axis. Why? . . . because anything that spins cause the universe to spin around it. Similarly, the back-and-forth y-axis mathematical point has a spin about the y-axis and causes the point on the x-axis to orbit the spinning y-axis spinning point. Each one of these two circles creates a spinning sphere that spins about a 45 degree axis and each point speed is vₒ with a spherical spin speed vₒ=λₑfₑ; thus these two points, model the behavior of an electron when they exhibit the negative charge (where spin speed vₒ is less than c; this is the making of an electron. This electron occurs for n=1 and is a sphere of radius re, spin frequency fₑ, spinning speed vₒ, and when this electron sphere is destroyed, two mathematical points are given off, with each mathematical point orthogonal to each other. Equation mₑ=(h/c²)fₑ yields the electron mass and since the spin speed v, is less than c, then the electron has a negative charge [i.e., recall formula for determining charge Is

$${E}_{t} = E [ 1 - \frac{{v}^{2}}{{c}^{2}} ] or \\ F = qE [ 1 - \frac{{v}^{2}}{{c}^{2}} ] ] .$$

What happens when n=2? The radius becomes rₑ/2, and the frequency is 2fₑ. The above analysis culminates in an rₑ/2 radius sphere, a spin frequency 2fₑ, spin speed vₒ, a sphere spinning about a 45-degree axis, and each point speed is vₒ with a spherical spin speed vₒ=λₑfₑ. This electron occurs for n=2, and is a sphere of radius rₑ/2, spin frequency 2fₑ, spinning speed vₒ, and when this electron sphere is destroyed, two mathematical points are given off with the two mathematical point orthogonal to each other. Equation m₂ₑ=(h/c²)2fₑ yields the electron mass, and since the spin speed vₒ is less than c, then the electron has a negative charge.

At n, the radius becomes rₑ/n, and the frequency is nfₑ. The above analysis culminates in an rₑ/n radius sphere, a spin frequency nfₑ, spin speed v, a sphere spinning about a 45 degree axis, and each point speed is v, with a spherical spin speed vₒ=λₑfₑ, this electron occurs for n=n, and is a sphere of radius rₑ/n spin frequency nfₑ spinning speed vₒ, and when this electron sphere is destroyed, two mathematical points are given off with the two mathematical point orthogonal to each other. Equation mₙₑ=(h/c²)nfₑ yields the electron mass, and since the spin speed v. is less than c, the electron has a negative charge.

This electron creating process creates smaller and smaller electrons with masses approaching infinity, and because Tₙₑ=(h/k)nfₑ, the temperature also approaches infinity. However there is a limit to the minimum electron radius, which is 3 rₒ or 3 times the photon's radius. Which in turn limits the frequency, mass and temperature. It is these mathematical points in the Mathematical Universe representing photons (see FIG. 5) in real space.

### The Making of an Atom

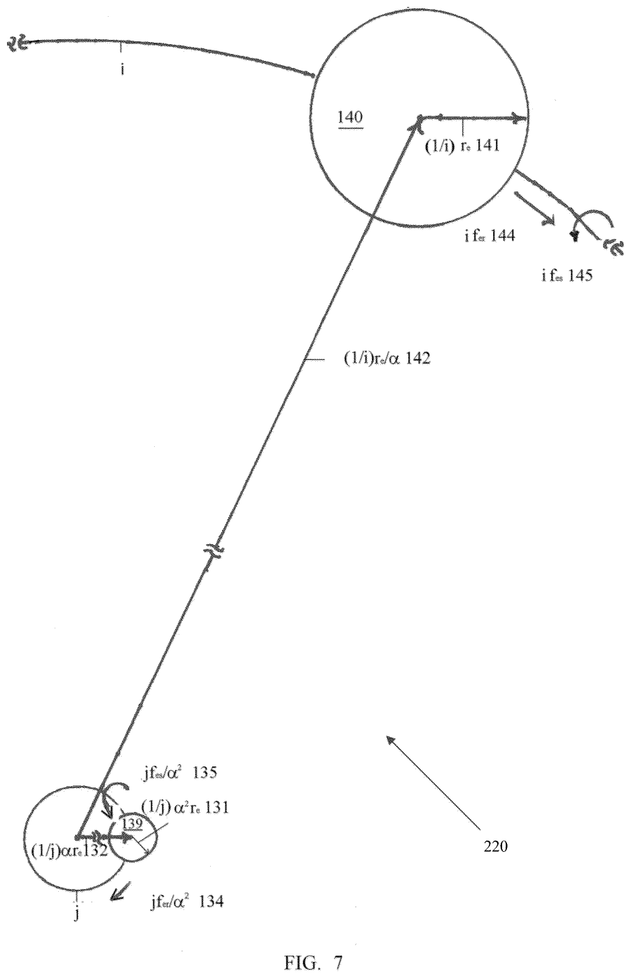

Now that we have Electrons, we will use the Atomic Model for an Electron to make an Atom (FIG. 7). One of the first aspect to note about an Atom is that the Atom is electrically neutral, and although the prevailing consensus is that a negative electron orbits a positive nucleus, this is quite disturbing because an electron separated from a proton is a dipole, and there is no physical way of getting a zero, or neutral electric field, but reality is that the atoms are electrically neutral, therefore they have a zero electric field. In our model, as previously explained the equation Eₜ=E[1−v²/c²] easily accomplishes this provided the mathematical point (i.e., Sphere) travels at speed c there is no electric field!

All atomic particles must travel with speed c, while traveling in a vacuum, where atoms form, and chemical reactions take place.

The maximal orbital frequency of any particle must be less than or equal to the particle's spin frequency.

The product of the orbiting mass and the orbiting radius must be mere/a; which remains true, no matter which orbit the electron is in.

The final rule is that the atomic mass, m is the sum of each particle's mass in both the outer and inner electron configurations (resulting from the corresponding increase in mass, generated from the orbital and spin frequencies; thus m=mₒ+mₛ=2mₑ outer plus 2mₑ/α² inner for each electron, where mₒ=mₛ=mₑ.

To reduce the complexity of introducing the description of the new Atomic Model of the Atom, we will: a) start with a description of the simplest Atom, Hydrogen; and b) in the figures we will not only follow the traditional preference of using reference numerals to describe the Atom; but we will also include familiar reference letters and abbreviations of names of parts of the atom in the description.

Upon examination of FIGS. 4 and 4A, representing the Mathematical Universe 110 and FIG. 4B, representing the Real Universe 220, note that in both cases, the Sphere is traveling in the direction of the positive x-axis 112 at a speed of vₒ 122, where vₒ<c, therefore the Sphere has a negative charge and has a spin frequency fₒ 126, and radius rₒ 121 in FIG. 4 and R 121 in FIG. 4B. Thus FIG. 4B forms the basis for the making of an Atom. Since the CMBR contains a sea of charged particles (i.e., charged spheres 130, see FIG. 5; or electrons in the Real Universe 220 in FIG. 4B). Examination of FIG. 7, an Atom in the Real Universe 220, and using Hydrogen for example, for this electron to travel in an outer orbit of an atom, it has to orbit the center of the atom 000 with a frequency fₑ 144, with speed c, whereby its charge becomes zero; the orbital radius, for this outer electron must be rₑ/α 142, and the spinning frequency of the electron is fₑ 145. Note that while the orbital frequency and spin frequency are both equal to fₑ, when there are adjacent orbits with electrons traveling in the same direction (i.e., repelling) or opposite direction (i.e., attracting), the orbiting frequency fₑ becomes fer and the spin frequency fₑ becomes fₑₛ which are different because of the repulsion or attraction from the electron(s) in the adjacent orbit(s); however, the orbiting frequency is always less than or equal to the spin frequency. This spin electron causes the space around it to go at speed c. As for the particle's (i.e. inner electron) orbital radius is αrₑ 132, the orbital frequency would be fₑ/α² 134 and the spinning frequency of the particle (i.e. inner electron) would also be fₑ/α² 135 with a particle (i.e. inner electron) radius α²rₑ 131 to give a particle (i.e. inner electron) mass 2 mₑ/α² (half due to orbital frequency and the other half due to spin frequency); which is different from the outer electron configuration mass, which is 2mₑ. For the outer electron, the moment arm is (2)mₑ(rₑ/α), and for the inner electron, the moment arm

$$( ( 2 ) ( \frac{{m}_{e}}{{α}^{2}} ) ( α {r}_{e} ) = ( 2 ) {m}_{e} ( {r}_{e} / α ) ;$$

thus both electron moment arms are equal.

The mass of the electron configuration for the orbiting outer electron is 2mₑ and for the orbiting inner electron configuration, the mass is 2mₑ/α² giving a ratio of outer electron mass to inner electron mass of α² or 1/18769 and not the electron to proton ratio of 1/1840. With i=1, this (see FIG. 7) is therefore a Model for the element Hydrogen.

### DETAILED DESCRIPTION OF THE SECOND EMBODIMENT OF THE INVENTION

Now that we have an Atomic Model of an Atom, we can use the model to provide a description of the second embodiment of the invention; which is to use it to model outer and nucleus electron configurations for Elements. Continuing to use the mathematical universe as a staging area and using known facts about the Elements, results from experimentation and research, to give us insight into selecting one configuration over another. We continued examining Elements from the beginning of the periodic table. The next element is Helium, outer orbit 1 has two opposite spin colliding electrons. Inner orbit 1 also has two opposite spin colliding electrons. The result is that photon space matrix collides and then reverse, only to collide again, and continues in this way at infinitum, thus no universe orbits the colliding electrons, hence the Helium atom has zero valence electrons; but the central attraction (i.e. gravitational force) does not change direction. However, a key tenant of our new Atomic Model is that for the most stable atom of an Element, one should use the smallest possible number of electrons for the electron configurations of said atom of an Element; and thus minimize the electron interactions by having the outer orbiting electron orbiting orthogonally; for example, the outer electron orbiting the x-axis and the inner electron orbiting the y-axis.

To accomplish this, we introduce the concept of two electrons traveling in a single orbit, whereby one of the electrons travel in one direction, with the other electron traveling in the opposite direction in the same plane; thus, creating electron collisions along said xy plane. Note that the characteristics of the Element will dictate the electron configuration. In the case of Helium, for the outer electron configuration, one plane is needed for the single head-on colliding electrons along the xy plane; and for the inner or nucleus electron configuration, an orthogonal plan; e.g., xz or zy for the single head-on colliding electrons in the nucleus; b) with 2 electrons colliding, in the inner and outer orbits, Helium cannot interact with other external electrons, in the 1^{st} orbit of both the inner and outer electron configurations. Two outer electrons and two heavier inner electrons; whereby each outer electron has an electron configuration mass of 2 mₑ plus each electron has an added mass, 2mₑ from the [2 for spin, 2 for orbiting and 2 for collisions] collisions, for a total outer electron mass of 8mₑ. Similarly, each inner electron has an electron configuration mass of (2mₑ/α²) plus each electron also has an added mass of 2mₑ/α² from the collisions for a total inner mass of (8m./α²). Thus, for Helium, the total mass for the Atom is (8 mₑ+(8mₑ/α²))=(4 m+(4 m/α²)) for outer and inner electron configurations; Note m=2 mₑ.

Note that, in the conventional model, because there are only two electrons and two protons the mass difference must represent two neutrons, but there are no atomic protons or neutrons in the Applicant's mathematical universe. Because there is no net spin, the outer Helium electrons cannot interact with any other external electron, because the spin frequency reverses spin direction with a 2fₑ frequency. Because the two electrons collide, the two electron spheres vibrate causing them to create different spectral lines from the usual non-vibrating electrons, which is Hydrogen's spectral lines.

Now that we have discussed the key features and electron configurations of a couple of the simpler atoms, we can use them as building blocks to construct the new model of the electron and using Hydrogen/Helium as examples of the new atomic structures. We can proceed to building the Atoms of the known Elements.

We will start by capturing those electrons from the CMBR with the energy required to settle into the first (or Valence orbit) of the outer orbital atomic structure or the first orbit of the nucleus of the atomic structure. But first, we will need to outline the means for binding fundamental atomic structures together.

Means for Binding Fundamental Atomic Structures Together: the means for binding atomic structures together manifest itself in one or more existing forces: including, centrifugal force, centripetal force, and spin forces.

For Example, the Atom: means for binding the atom together, the purpose of which is to establish and maintain a stable electron configuration; whereby balancing the repelling and attractive forces of the atom to establish and maintain stability.

Key points about the means for binding a stable atom together:
In a stable atom, the centripetal force (i.e., also called gravitational force) and centrifugal force balance each other out; thus, neither has more attraction/repulsion influence than the other; i.e. they are equal;
Recall that in an atom in a vacuum, orbiting electrons must orbit with an orbital speed c, therefore said electrons have no charge, and the electromagnetic forces are zero;
Given the above two points, we turn our attention to electron spin as an attractive, or repulsion forces. Note that two “opposite direction” spinning spheres attract each other, whereas two same direction spinning spheres repel each other. The resulting binding or repelling force will vary in strength depending on the spin frequency and distance between the spheres (i.e., electrons).

For those electron configurations that are formed where the repelling and attractive forces are unbalanced, the resultant atoms are unstable, thus for example creating radioisotopes of the atom, said configurations are short lived compared to the stable configuration.

The expression for the spinning sphere's equation is (4/3)πR³f², therefore the outer electron's spin expression is (4/3)mrₑ³fₑ², but the inner electron spin expression is (4/3)π(α²rₑ)³(fₑ/α²)²=(4/3)πα⁻²rₑ³fₑ² which means the inner electron's spin is 1/α² or 18,769 times faster than the outer electron's spin.

The outer electron centrifugal acceleration (c²/rₑ/α)iᵣ=(αc²/rₑ)iᵣ is away from the orbital center. The inner electron centrifugal acceleration is c²/(αrₑ)iᵣ. The inner electron acceleration is 1/α² or 18,769 times greater than the outer electron acceleration.

Interacting with another outer orbit electron yields the force equation k(f₁f₂)/(r_{1,2})². The outer electron's parameters (see FIG. 7) are mass i2m_{c}, spin frequency ifₑ, 145, radius rₑ/i 141, orbital radius rₑ/(iα) 142, and orbital frequency ifₑ 144. The inner electron's equation with another inner electron kf₁f₂/(r_{1,2})². The inner electron's parameters are mass (j2mₑ)/α², spin frequency jfₑ/α² 135, radius (α²rₑ)/j 131, orbital radius αrₑ/j 132, and orbital frequency jfₑ/α² 134.

Two outer electrons, where one in orbital in, and the other in orbital i₂, has the force equation k(i₁i₂)fₑ²/[(rₑ/α)(1/i₁−1/i₂)]²=k(i₁i₂)³α²f_{c}²/[rₑ(i₂−i₁)]², whereas two inner electrons, where one is orbital j₁, and the other in orbital j₂; has the force expression k(j₁j₂fₑ²/α⁴)/[(rₑα)(1/j₁−1/j₂)]²=k(j₁j₂)³(fₑ²/α⁶)/[rₑ(j₂−j₁)]², which is greater force than the outer orbit interaction force.

These two forces bind or repel the two interacting electrons. With a greater spin force than the outer electron, the inner electron has the greater binding or repelling force. Since the inner electron has the greater spin force, then the inner electron has the greater binding or repelling spin force. The atomic model of the present invention has outer and inner electron bonding, or repulsion. The value of k becomes crucial for bonding and nuclear stability. The initial estimate is that k=hrₑα⁴/fₑ, which allows for atom stability with i₂<60 and i₁<59.

Since there are atomic mass greater than the 120 the elements with atomic numbers greater than 60 may have colliding electrons at greater than atomic number 60. For instance, orbital [45] collisions bring up an atomic mass of 180 and with an orbital at 60 the atomic mass is 240. For interacting atomic numbers greater than 60 and 59, the atom nucleus orbits are unstable.

The inner electron centrifugal force is (nmₑ)(c²/(αrₑ)), and the binding, or repelling force on the outer orbiting electron is the force due to the spin force interaction. For example, the Hydrogen atom has one outer, and one inner electron. The outer electron's mass is mₑ=(h/vₒ²)fₑ with a centrifugal force mₑαc²/rₑ=(h/vₒ²)αc²fₑ/rₑ=hfₑ/(αrₑ) whereas the inner electron has mass (mₑ/α²)=(h/vₒ²)fₑ/α² with a centrifugal force (h/vₒ²)c²fₑ/(α³rₑ)=hfₑ/(α⁵rₑ)=hfₑ/(α⁵rₑ), yields a spin force value α², times the centrifugal and centrally attractive forces, which must be greater than the binding or repelling spin force between the inner and outer electron, and is kfₑ²/rₑ². Making k=hrₑα⁶; As the inner electrons number increases, the spin forces increase resulting in inner electrons instability.

The examples below using Hydrogen and Helium, illustrate how the above-described forces interact to form atoms and compounds.

The Hydrogen atoms have an outer electron and an inner electron and both orbitals have equal and opposite radial forces that are much greater than the spin forces, but nevertheless the spin forces are present, and increase the orbital radius, when the inner and outer orbitals spin in the same direction. The Hydrogen compound H₂ consists of two Hydrogen atoms that bind through the spin forces. The two outer “opposite spin” direction [outer] electrons [spin] force is kfₑ²/(2rₑ)², whereas the inner electron spin force is kfₑ²/α²(2rₑ)², a much greater binding force. All orbital electrons may join to create binding or repulsive forces, and bonding is not just due to the outer electrons.

Helium has 2 outer and 2 inner electrons. Both outer electrons are in orbital 1 with opposite spins, and orbital speed c. These two colliding electrons double each electron's frequency, Doubling the frequency of each outer electron yields 4 times the outer electron's mass, with only two outer electrons present. The same process occurs in the first inner orbital leading to the helium mass being 4 times the hydrogen mass. There are no neutrons.

Collision in both inner and outer electrons leave no binding with any other element. Note that increasing Orbital collision increases frequency, therefore increase mass. Electron orbital collisions give an etiology for helium's spectral lines. A new frequency set is present to explain the unexplainable—helium's wavelengths. The electron collisions cause vibrations, thus creating a new set of wavelengths, in the atomic spectral lines.

The essential facets of the present invention will be explained by way of examples of the atomic configurations of the elements built from atoms using the machine and methods of the present invention.

Key points to note while reviewing said atomic configurations of the Elements are outlined in the following principles.
1. The entire atom consists of only electrons; therefore, there are no protons or neutrons.
2. In the atom, electrons orbit at the speed of light, c.
3. The equation determining charges is Eₜ=E(1−υₒ²/c²);
   a. All stable atoms have no charges.
4. The equations determining mass are m=(h/υₒ²)f and m=(k/(λₑ υₒ²))T;
   a. As electrons inhabit deeper orbits (starting with i=1 to i=137, for outer orbits and j=1 to j=137 for nucleus orbits) in the atom, the electron(s):
      i. Both orbital and spin frequencies become higher; i.e., from fₑ to ifₑ for each electron in the ith outer orbit and (fₑ/α²) to j(fₑ/α²) for each electron in the jth nucleus orbit,
      ii. Each electron become physically smaller; i.e., due to said increase in frequencies and their radii become shorter, from rₑ to rₑ/i for outer orbits and from α²rₑ to α²(rₑ/j) for nucleus orbits; however
      iii. Each electron's mass increases proportionately as said frequencies increase from 2mₑ to i(2mₑ) for outer orbits and from 2mₑ/α² to j(2mₑ/α²) for nucleus orbits; thus, varying mass electrons inhabit all atoms; Note m=2mₑ,
5. Two electrons spinning in opposite directions attract. Two electrons spinning in the same direction repel.
6. Atoms with orbits that have “head-on” collisions, require that the plurality of electrons in said orbits must be even. An even number of said electron results in the plurality of electrons kᵢ, in the ith orbit be divided by 2, where kᵢ/2 equals the number of sets containing an even number of electrons in the i^{th} orbit; the plurality of electrons must have half of them spinning in one direction and the other half spinning in the opposite direction. The resultant orbital and spin frequencies increase by a factor of kᵢ/2.
   a. the corresponding frequency dependent parameters also increase by a factor of kᵢ/2 as follows:
      i. Orbital and spin frequencies become higher, for any ith orbit with collisions; increases to kᵢ(2fₑ); for each electron, 1 for each orbital frequency increase and 1 for each spin frequency increase; similarly for nucleus orbits with collisions resulting in frequency increases to kⱼ(2fₑ/α²),
      ii. Electrons become physically smaller (i.e., as their radii become shorter, from rₑ to rₑ/i for outer orbits and from α²rₑ to α²(rₑ/j) for nucleus orbits; however,
      iii. Concurrently their mass increases proportionately; increasing to kᵢ(2mₑ) for outer orbits and to kⱼ(2mₑ/α²) for nucleus orbits; thus, varying mass electrons inhabit all atoms.
   7. The equation determining orbital and spin speed in terms of frequency is λf=vₒ; where λ=2πr.
   8. Fine Structure Constant, α=1/137.

As expected, the total number of electrons in each Element plays a major role in building the most stable electron configuration of said Element that binds said plurality of electrons together in predisposed configurations to create atoms of each element. The number of electrons largely determines the electron configuration; but alternative configurations do occur; which fall into several categories.

Note that the atomic model electron configurations for the Elements becomes more complicated and therefore more difficult to configure as reliably and accurately as one moves from the lighter elements (i.e., as listed by mass in the Periodic Table) to the heavier elements. Therefore, as one proceeds through the list of elements in order of increasing mass, to assign the best fitting electron configuration, one must ensure that said configuration matches the element's real-world features and characteristics. Thus, more scientific work, including experimentation, deep thinking, research, and collaboration must be performed to model and compare each element's real and actual features, characteristics, anomalies, etc. against the expected theoretical behavior of multiple alternative models to select the best electron configuration that most closely models the elements' real features, characteristics, anomalies.

Electron Configurations that Model Typical Atoms, Follows
Single Orbit—without Collisions (FIG. 7)

Outer Orbiting electrons: the outer electron 140 configuration for the single orbit, “kᵢ” (where i is the i^{th} orbit; however if it is the outermost orbit 1, it is traditionally called the Valence orbit; and kᵢ is the number of electrons in the i^{th} orbit), let's assume kᵢ=k₁=1 for this example but typically consists of a plurality of kᵢ electrons, each with a radius rₑ 141 and orbiting a center of mass with an orbital radius rₑ/α 142 moving at an orbital speed of c in a clockwise [arbitrarily selected] direction with orbital frequency fₑ 144 as shown by arrow; thus using the Right Hand rule from physics with thumb facing in the direction of the electron's 140 motion, resulting in an electron 140 counter-clockwise spin with spin frequency fₑ 145 as shown by circular arrow. Said frequencies causing each electron 140 to have a total mass for each outer orbiting electron 140 of m=2 mₑ=m_{c}+mₛ, due to the orbital frequency fₑ 144 and spin frequency fₑ 145 respectively and where m is the mass of a single electron 140 and mₑ=mₛ=mₒ where mₛ and mₒ is the mass due to the spin frequency and the mass due to the orbiting frequency, respectively.

Given that each electron orbits at the speed of light c, the outer electrons each have no charge (see points 2-3 above).

Inner Orbiting electrons (traditionally called the nucleus): the inner electron configuration is like that of the outer orbiting electron configuration (with notable differences); in that its single outermost orbit, “kⱼ where j=1” also consists of one electron, but each with a much smaller radius α²rₑ 131, and orbiting the same center mass with a much smaller orbital radius αrₑ 132 moving at an orbital speed of c. Each said electron 139 has an orbital frequency fₑ/α² 134 as shown by the arrow; also, with spin frequency fₑ/α² 135 as shown by the circular arrow.

This dramatic reduction in size and increase in mass of the inner electron configuration vs outer electron configuration is due to the increase in each inner electron's 139 spin frequency fₑ/α² 135, orbital frequency fₑ/α² 134 and the resulting reduction in its radii compared to the outer electron 140; causing each electron 139 in the inner orbit to have a total mass of:

$$m / {α}^{2} = 2 {m}_{e} / {α}^{2} = ( 1 / {α}^{2} ) ( {m}_{o} + {m}_{s} ) .$$

Single Orbit—without Collisions: Total Mass for the Entire Electron Configuration.
Thus, the total mass of the atom's single orbit electron configuration (FIG. 7) is:

$$( m ) ( {k}_{i} + ( {k}_{j} / {α}^{2} ) ) = ( 2 {m}_{e} ) ( {k}_{l} ) ( 1 + ( 1 / {α}^{2} ) ) \qquad ( 1 )$$

Where i=j=1 and k; =kⱼ=kⱼ=1 is the number of electrons in the single outer and inner orbits, m=2mₑ.

### Example—Hydrogen

We know from experience, experimentation, and observations that the Hydrogen atom has a single outer electron and using the Present Invention to build the Hydrogen Atom using the “all” Electron Model, the nucleus or inner electron configuration would also consist of one electron (i.e., kᵢ=kⱼ=k₁=1, in equation (1) above) and therefore the total Electron Configuration Mass for Hydrogen (in m and mₑ respectively) is: m(1+(1/α²))=2mₑ (1+(1/α²)).

### Electron Configuration (FIG. 7)

Single Orbit—with Collisions

Conditions:
kᵢ and kⱼ must contain an even number of electrons in any referenced i^{th} and/or j^{th} orbits that have collisions; where kᵢ and kⱼ are the number of electrons in the “,th” orbit of the outer electron configuration and “j^{th}” orbit of the inner Electron Configuration respectively.
In said “i^{th}” orbits and “i^{th}” orbits that have collisions, half of the electrons are traveling in a direction opposite to the direction of the other half; thus, causing one-on-one collisions of the electrons in each of said orbits.

When an even number of outer orbiting electrons collide (where the kᵢ=k₁ is an even number of colliding electrons in a single outer orbit), each electron only travels half its circumference before it collides, therefore there are now two collisions in the same timeframe, effectively causing both spin and orbital frequencies in the single outer orbit to double, from kᵢ fₑ to kᵢ 2fₑ. Similarly, if the inner orbiting electrons also colliding, this will cause both spin and orbital frequencies in the single inner orbit to double from kⱼ(fₑ/α²) to kⱼ(2fₑ/α²).

Said increase in the electron configuration frequencies in the single orbit result in a corresponding increase in the total electron configuration mass in equation (1) with collisions (in m and mₑ respectively) to:

$$2 ( m ) ( {k}_{1} ) ( 1 + ( 1 / {α}^{2} ) ) = ( 2 ) ( 2 {m}_{e} ) ( {k}_{1} ) ( 1 + ( 1 / {α}^{2} ) ) ; \qquad ( 2 )$$

Where kᵢ=kⱼ=kᵢ and I=j=1 is the outermost orbit number 1 in the outer and inner electron configurations respectively; k₁=2, is the number of electrons in the single outer and inner orbits.

### Example—Helium

Said Helium atom has kᵢ=kⱼ=k₁=2 outer electrons in the same i=1^{st} outermost orbit, traveling in opposite directions; hence they collide; and similarly for the 2 inner electrons. Using the Present Invention to build the Helium atom, the total Electron Configuration Mass for Helium is:
4m (1+(1/α²))=(2)4mₑ (1+(1/α²)), where m=2mₑ is the mass of a single electron and k₁=2, is the number of electrons in the single (i^{th}=1^{st}) outer and (j^{th}=1^{st}) inner orbits.

### Electron Configuration

Two or More Orbits—without Collisions

Outer Orbiting electrons: the electron configuration for the outermost orbit, “kᵢ^{th}” (where kᵢ is the number of electrons in the i^{th} orbit; and when i=1 outermost orbit, traditionally called the Valence orbit) consists of k₁ valence electrons, each with a radius rₑ, and an orbital radius rₑ/αᵢ with an orbital frequency i*fₑ, with clockwise orbital spin direction (arbitrarily selected), orbital speed c, each with a mass of m=2mₑ=mₛ+mₒ=(h/υₒ²)fₑ (notes 5-6 above, where mₛ=m_{c}=mₑ. With k₁=1 electron, this is identical to the 1^{st} and only outer orbit of the Hydrogen atom.

Total mass of the Valence (1^{st}) outer orbit is k₁(m)=k₁(2mₑ)=k₁(mₛ+mₒ); where k₁=1 electron.

For the next occupied outer orbit (i.e., “kith” orbit), there are kᵢ electrons, each with radius rₑ/i, spin frequency ifₑ, orbital radius (1/i)(rₑ/α), orbital frequency i*kᵢfₑ, orbital speed c, each also with a mass (i*kᵢm)=(i*kᵢ2mₑ).

The total mass collectively attributable to the electrons in the “i^{th}” outer orbit is (i*kᵢm), where kᵢ is the number of electrons in the “i^{th}” orbit.

Similarly, the general formula for the total mass of any occupied outer orbit i of electrons is ((i kᵢ) m)=(i kᵢ 2mₑ), where kᵢ is the number of electrons in the i^{th} orbit and i is: ranges from 1 to 137.

Thus, for the general formula for the total outer electron configuration mass is:

$$m ( 1 {k}_{1} + … + {ik}_{i} + … + 137 {k}_{137} ) = m {\sum }_{i = 1}^{137} ( i {k}_{i} ) = 2 {m}_{e} {\sum }_{i = 1}^{137} ( i {k}_{i} ) .$$

Inner Orbiting electrons: similarly, for the inner electron configuration consists of kⱼ electrons (1^{st} orbit), each with a radius α²rₑ sphere, spinning frequency fₑ/α² orbiting with a radius are and orbital frequency fₑ/α², orbital speed c, and mass m/α²=2mₑ/α². With k₁=1, this is identical to the 1^{st} and only inner orbit of the Hydrogen atom. For the next occupied inner orbit kⱼ, there is kⱼ electrons, each with a radius α²rₑ/j, spin frequency j*(fₑ/α²), orbital radius αrₑ/j, clockwise orbital frequency j*(fₑ/α²), orbital speed c, each also with a mass jkⱼ(m/α²)=jkⱼ (2mₑ/α²);

The total mass of the j^{th} inner orbit is jkⱼ(m/α²), where kⱼ is the number of electrons in the j^{th} orbit.

Similarly, the General Formula for the Total Mass of any Occupied Inner Orbit kⱼ is:
jkⱼ (m/α²)=jkⱼ (2m_{c}/α²), where kⱼ is the number of electrons in the j^{th} orbit and j ranges from 1 to 137.

Thus, for the general formula for the total inner electron configuration mass is:

$$( m / {α}^{2} ) ( 1 {k}_{1} + + j {k}_{j} … + 137 {k}_{137} ) = ( m / {α}^{2} ) {\sum }_{j = 1}^{137} ( j {k}_{j} ) = ( 2 {m}_{e} / {α}^{2} ) {\sum }_{j = 1}^{137} ( j {k}_{j} ) ;$$

note m=2mₑ.

The total mass for the entire electron configuration of the atom (without collisions) is:

$$m ( 1 {k}_{1} + … + {ik}_{i} + … + 137 {k}_{137} ) + ( m / {α}^{2} ) ( 1 {k}_{1} + … + j {k}_{i} + … + 137 {k}_{137} ) = m {\sum }_{i = 1}^{137} ( i {k}_{i} ) + ( m / {α}^{2} ) {\sum }_{j = 1}^{137} ( j {k}_{j} ) = 2 {m}_{e} ( {\sum }_{i = 1}^{137} ( i {k}_{i} ) + ( 1 / {α}^{2} ) {\sum }_{j = 1}^{137} ( j {k}_{j} ) ) ; \qquad ( 3 )$$

$$where m = 2 {m}_{e}$$

Where kᵢ and kⱼ are the number of electrons in the i^{th} and i^{th} orbits respectively; and both i and j ranges from 1 to 137.

### Electron Configuration

Two or More Orbits—with Collisions

### Conditions:

for any orbit i that has kᵢ head-on colliding electrons, kᵢ must be an even number of electrons; where kᵢ=number of electrons in said outer orbit.
in said “i^{th}” orbit, half of the electrons are traveling in a direction opposite to the direction of the other half; thus, causing collision of the electrons in that orbit.
When the kᵢ electrons in the “i^{th}” outer orbit collide, it causes both spin and orbital frequencies of said colliding outer electrons to double. Similarly, when the k_{J} electrons in the “j^{th}” inner orbit collide, it results in the corresponding spin and orbiting frequencies of said colliding inner electrons to double.
Doubling the outer and inner electron configuration frequencies, result in doubling the total mass of said electrons for each orbit with colliding electrons; resulting in a total electron configuration mass for the Atom calculated as follows:

$$For non - colliding orbits : ( 2 {m}_{e} ( {\sum }_{i = 1}^{137} i ( {k}_{i} ) + ( 1 / {α}^{2} ) {\sum }_{j = 1}^{137} j ( {k}_{J} ) ) ) ; and \qquad ( 4 )$$

$$for colliding orbits : ( 2 {m}_{e} ( {\sum }_{i = 1}^{137} i ( {k}_{i} ) + ( 1 / {α}^{2} ) {\sum }_{j = 1}^{137} j ( {k}_{J} ) ) )$$

Where kᵢ is the number of electrons in the i^{th} orbit; and kⱼ is the number of electrons in the j^{th} orbit; when the i^{th} orbit contains an even number of electrons, where half are traveling in the opposite direction from those in the other half of the i^{th} orbit (i.e., they are colliding). Similarly, when the j^{th} orbit contains an even number of electrons, where half are traveling in the opposite direction from those in the other half of the j^{th} orbit (i.e., they are colliding).
For atom calculations that include orbits that contain no collisions, and orbits that contain collisions, one must use both of the above equations—labeled (4); and for all empty orbits, set kᵢ's and kⱼ's equal to zero.

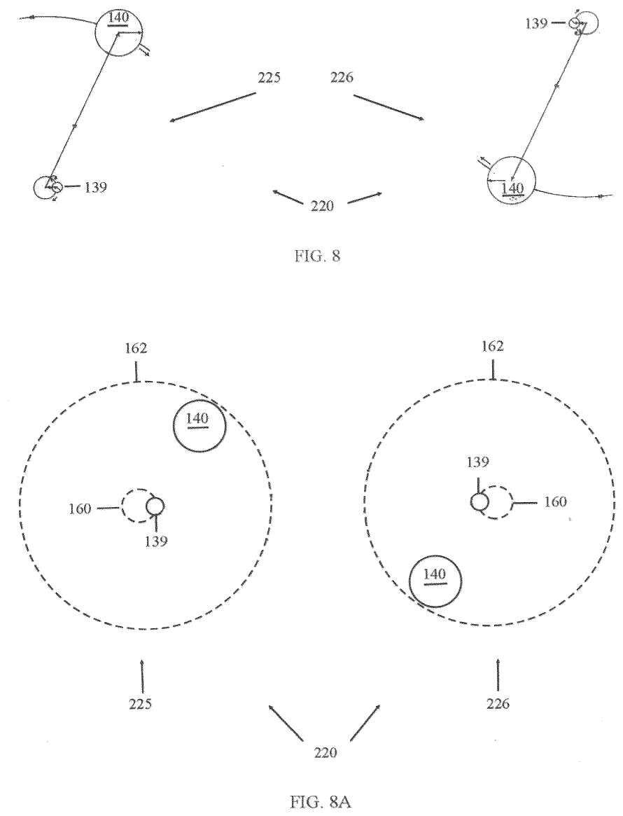

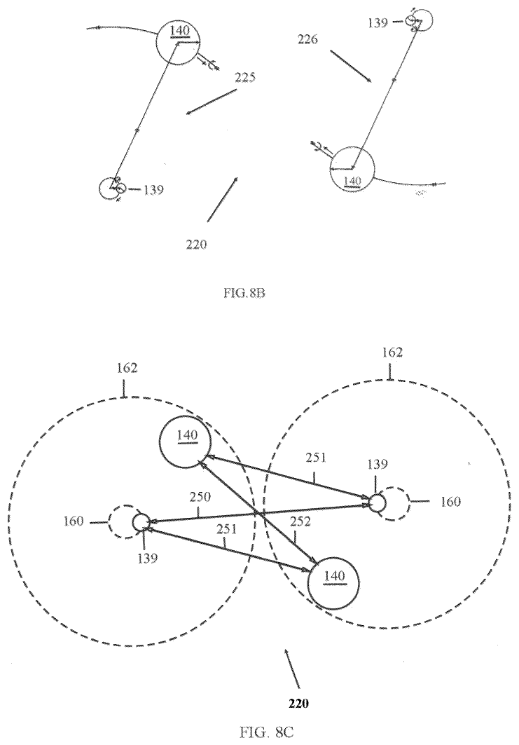

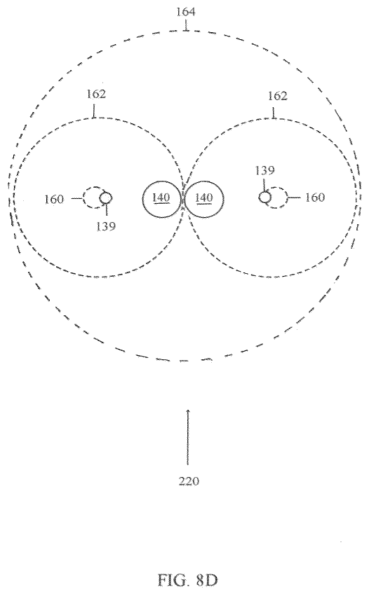

The Making of a Molecule: Now that we have Atoms let us use them as a building block to create a Molecule (see FIGS. 8, 8A, 8B, 8C, and 8D).

Using the Hydrogen Molecule, H₂ as an example FIG. 8 shows two Hydrogen Atoms 225 and 226 in the Real Universe 220 such that, the single inner electron configurations of each atom are attracted to each other due to their extremely high spin in opposite directions; which results in a strong Spin Binding Force between them. This is reflected in the diagrammatic view (see FIG. 8A) again showing a Real Universe 220 of the two Hydrogen atoms, each having come under the sphere of influence of the other's spin binding force, which in turn draws them ever closer to each other. The path of the inner electrons of the atom on the left 225 and right 226 (FIG. 8), each forms a sphere shown by the dashed lines 160 (FIG. 8A). The path of the outer electrons of the atoms on the left and right, each forms a sphere shown by the dashed lines 162. Recall our earlier discussion concerning the assertion that anything that spins, causes everything in the Universe to spin around it (swirl), thus causing said nucleus of the electron on the right (FIG. 8) to spin around the nucleus of the electron on the left (FIG. 8); and similarly said nucleus of the electron on the left spins around the nucleus of the electron on the right. Their strong Spin Binding Force attraction shown by the double arrow 250 (see FIGS. 8B and 8C) causes the inner electron configurations of both Hydrogen Atoms to come as close as possible to each other without overlapping or interfering with each other's orbiting or spin paths

In addition, the single outer electron configurations of the two atoms are also spinning in opposite directions from each other, resulting in a somewhat weaker opposite spin attraction shown by the double arrowed line 252 (binding force) between them (only α² or the fraction 1/18,369 as strong as the inner electron attraction)! However, the weaker Spin Binding Force still contributes to the attraction of the outer electron configurations of both Hydrogen Atoms 225 and 226, to draw towards each other like the inner electron configurations! Note that in FIG. 8D, the two Hydrogen Atoms outer and inner electron

configurations are now drawn as close to one another as possible and still allow the respective atoms to remain unchanged, separate, and independent; they are bound together by their opposite spin attraction! Note that the path traveled by the electrons from the two atoms that make up the Hydrogen Molecule forms spheres 160 and 162 for the inner and outer electron configurations respectively, and the path traveled by the two atoms swirling around each other shown by the dashed line 164 that encapsulates the entire Molecule forms a sphere. The formation of these spherical encapsulations is shown in phases, as the two Hydrogen Atoms come together to form the Hydrogen Molecule in FIGS. 8A, 8C and 8D. Also note that the shape of the encapsulation of the electrons, hydrogen atoms, and hydrogen molecule is assumed to be spherical, but more experimentation and research would have to be done to verify the actual shape of the encapsulations.

What is claimed is:

1. A new Method for Modeling an Atomic Structure(s), starting with a plurality of photon(s), and modeling an electron(s), an atom(s), a molecule(s), and a compound(s); and using said new Method for Modeling said Atomic Structure(s) further comprising:
a. Using a Mathematical Universe as a staging area, said Mathematical Universe further comprising:
i Using a 3-dimensional cartesian coordinate system; further comprising
i.) assembling a plurality of solid mathematical points, each a sphere homogeneously distributed throughout said 3-dimensional cartesian coordinate system; and further comprising:
a) assembling said solid mathematical point(s), with a volume V, a radius rₒ, moving at a constant speed υₒ; υₒ being less than a speed c, defined as speed of light in a vacuum; said movement υₒ also imparts a torque perpendicular to the direction of movement which imparts a spin and therefore having a spin frequency fₒ; said movement at said speed less than c, in turn imparts a negative charge to each said solid mathematical point(s); resulting in a sea of said negatively charged solid mathematical point(s) throughout said Mathematical Universe;
b) Establishing said plurality of solid mathematical point(s) as a function of the number of said solid mathematical point(s) in a defined 3-dimensional space; resulting in a sea of 389 said negatively charged solid mathematical points, located in a cubic centimeter;
c) Deriving the calculation of a Fine Structure Constant α=1/137, from said 389 solid mathematical points in a cubic centimeter; where each said negatively charged solid mathematical point(s) is a minimal distance of 1.37 mm from its nearest neighbors;
b. Substituting a Real Universe for the Mathematical Universe as the staging area; and
further comprising:
i) Asserting that the 3-dimentional cartesian coordinate system can be represented in said Real Universe;
ii) Asserting that said plurality of solid mathematical points, and said 3-dimentional sphere, can be represented in said 3-dimentional cartesian coordinate system of said Real Universe with all the same attributes attributed to said plurality of solid mathematical points, and said 3-dimentional sphere, in said Mathematical Universe;
iii) Asserting that motion of said real solid points (the Spheres) in any direction results in a torque placed on the solid points (the spheres) orthogonal to said direction, thus imparting spin to said real solid point;
iv) Asserting that as in the mathematical Universe, said ocean of negatively charged real solid points (the Spheres) throughout said Real Universe results in a sea of Photons, collectively called a Cosmic Microwave Background Radiation (CMBR) in said Real Universe;
v) Asserting that in the real universe the Photons move in a right angle, triangular wave; the right triangle has 2 equal sides of 1.37 mm, and the hypotenuse is (√2) 1.37 mm (or 1.94 mm);
vi) Asserting that said triangular waves collide and create a specific frequency and a specific wavelength standing waves in each of a three orthogonal axes; the specific frequency standing wave in each of a two orthogonal axes, creates said electron with the spin frequency of the standing wave's specific frequency, and constant spin speed υₒ; the remaining two pairs of said orthogonal axes similarly follow the same process to create said electrons; said electrons are created and maintained in a pool of electrons which consists of electrons with spin frequencies ranging from fₑ to fₑ/α³ different said frequencies and said wavelengths; whereby in the pool of said electrons, the number of electrons with said spin frequencies at the front end of said range is the largest number of said electrons by type and the electrons with spin frequencies at the back end of said range is the fewest number of said electrons by type;
c. Exploiting a scientific basis for an Equivalence of a mass to energy, an Equivalence of a mass to Frequency, an Equivalence of a mass to Temperature; further comprising:
i) Rotating of said Spheres, with corresponding said frequency, fₑ which creates said mass;
ii) Spinning of said Spheres, with corresponding said frequency, fₑ which creates said mass;
iii) Colliding of said Spheres, results in a radial vibration(s) in the Spheres at said frequency, fₑ which creates said mass;
iv) Leading to the use of only said electrons as a basic building block(s) for said new Method for Modeling said Atomic Structure(s);
d. Exploiting a scientific basis for a functional relationship between said orbiting frequency, said spin frequency, said collisions that create said radial vibrations in said Spheres at said frequency, said speed υₒ of said Spheres, said speed of light c, and an electrically charged Spheres; further comprising:
i) Asserting that c is the speed of light in a vacuum;
ii) Asserting that the only time any particle can travel at the speed of light, c is when the particle is in a vacuum;
iii) Asserting that when the spin speed υₒ is less than said speed of light c, said electrically charged Sphere has a negative charge;
iv) Asserting that when the spin speed υₒ is equal to said speed of light c, said electrically charged Sphere has zero charge;
v) Asserting that when the spin speed υₒ is greater than said speed of light c, said electrically charged Sphere has a positive electric charge;
e. Using said Means for Binding said Photons together to form said Electron(s), said Electron(s) together to form said Atom(s), said Atom(s) together to form said Compounds.

2. A new Method for Modeling the Atomic Structure(s) as recited in claim 1; further comprising:
a. Establishing a basic requirement(s) for said new Method for Modeling to follow when building said Atomic Structure of a Stable Element; further comprising:
i) Asserting that the key factor that determines a valence of the atom in the absence of strong evidence to the contrary, is that said valence is equal to the maximum number of hydrogen electrons that the atom can bind with;
ii) Asserting that the number of said electron(s) in the outer and inner orbits are equal; if not this electron configuration of the atom is unstable;
iii) Asserting that the sum of the moments of the outer electron configuration(s) is equal to the sum of the moments of the inner electron configuration(s); if not this electron configuration of the atom is unstable;
iv) Asserting that the binding and repelling forces of the atom must be balanced to ensure that the atom is stable; if not this electron configuration of the atom is unstable;
b. Determining the valence of the atom of said element;
c. Determining the electron configurations that the atom of said Element requires in the outer and the inner orbit(s) to exhibit the characteristics of the Element;
d. Capturing the required number of said electrons from said CMBR that satisfy the electron configuration requirements of each of the orbits of the atom of said Element;
e. Checking to ensure that the electron configurations provide a stable atom;
f. Checking to ensure that said Means for Binding the atom together, is adequate; if not the atom is unstable.

3. A new atomic model of an atom, consisting of an all electron structure in a vacuum; further comprising: an outer electron and an inner electron configuration; said electron(s) in said atom are moving in a orbit(s) and have a spin.

4. The new atomic model of an atom as recited in claim 3; further comprising:
a. said electron in said outer orbit, orbiting a nucleus and a common center at a speed of light c, and therefore has a zero charge; and further comprising:
i) the outer electron has a radius rₑ;
ii) the outer electron has an orbital radius (rₑ/α) from said common center;
iii) the outer electron has an orbiting frequency fₑ;
iv) the outer electron has a spin frequency fₑ;
v) the outer electron has a mass 2mₑ;
b. said electron in said inner orbit, orbiting said common center at said speed of light c, and therefore has said zero charge; and further comprising:
i) the inner electron has a radius α²rₑ;
ii) the inner electron has an orbital radius are from said common center;
iii) the inner electron has an orbiting frequency fₑ/α²;
iv) the inner electron has a spin frequency fₑ/α²;
v) the inner electron has a mass 2mₑ/α²;
vi) the total of said mass of said atom is 2mₑ(1+1/α²);
c. Means for binding said atom together, whereby establishing and maintaining a stable electron configuration, by balancing a repelling and an attractive force(s) of said atom; although other said electron configurations may form, creating an isotope(s) for example, but they are short lived compared to the stable electron configuration(s) of said atom(s) of an element(s).

5. The new Atomic Model of an Atom as recited in claim 4; whereby said new atomic structure of said Atom describes the Element Hydrogen.

6. The new Atomic Model of an Atom as recited in claim 3, further comprising:
a. A pair of electrons in a single outer orbit, said pair of electrons each orbiting said nucleus and said common center in opposite directions from each other at the speed of light c, and therefore each has said zero charge; and further comprising:
i) Said pair of electrons in said single outer orbit, colliding with each other, reversing directions, traveling for half the circumference of their orbit, then colliding again, and continue repeating the collisions again at infinitum; thus, the collisions halve the circumference, and consequently establishes a standing wave of vibrations that doubles the frequencies and the mass;
ii) Said pair of outer electrons each with a radius rₑ;
iii) Said pair of outer electrons each has the orbital radius rₑ/α from the common center;
iv) Said pair of outer electrons each orbiting at the frequency fₑ;
v) Said pair of outer electrons each spinning at the spin frequency fₑ;
vi) Said pair of outer electrons, each has a mass of mₑ due to said orbiting frequency of fₑ; also each has a mass of mₑ due to said spin frequency of fₑ, and because, at the collision point each said electron travels only half of the circumference, an electron collision occurs twice in the given time period, resulting in each said electron having a radial vibration; which doubles the orbital frequency to 2 fₑ and the spin frequency to 2 fₑ, of each said electron; note that the direction of spin for each said electron, also changes 180 degrees in the opposite direction. Thus, the total outer mass of said atom is: (2 mₑ/electron)(2 electrons/collision)(2 collisions)=8 mₑ;
b. Said pair of electrons in said single inner orbit, with each electron orbiting the common center in opposite directions from each other at the speed of light c, and therefore each has said zero charge; and further comprising:
i) Said pair of inner electrons in said single inner orbit, colliding with each other, reversing directions, traveling for half the circumference of their orbit, then colliding again, and continue repeating the collisions again at infinitum; thus, the collisions halve the circumference, which effectively results in a radial vibrations that doubles the orbital frequency and the spin frequency of each said electron and consequently doubles the frequencies and the mass;
ii) Said pair of inner electrons each has the radius (α²rₑ);
iii) Said pair of inner electrons each has the orbital radius are from the common center;
iv) Said pair of inner electrons each orbiting at the frequency fₑ/α²;
v) Said pair of inner electrons each spinning at the frequency fₑ/α²;
vi) Said pair of said inner electrons, each has said mass of mₑ/α² due to said orbiting frequency of fₑ/α²; also has said mass of mₑ/α² due to said spin frequency of fₑ/α² and because, at the collision point each electron only travels half of the circumference, said electron collision occurs twice in the given time period, resulting in each said electron having a radial vibration; which doubles the orbital frequency to 2 fₑ/α² and the spin frequency to 2 fₑ/α², of each said electron; note that the direction of spin also changes 180 degrees in the opposite direction; thus the total inner mass of said atom is: ((2 mₑ/α²)/electron)(2 electrons/collision)(2 collisions)=8mₑ/α²;
vii) The total mass of the atomic structure is 8mₑ (1+(1/α²));
c. Means for binding the atom together, whereby establishing and maintaining a stable electron configuration, by balancing the repelling and attractive forces of the atom; although other configurations may form, creating said isotope(s) for example, but they are short lived compared to the stable electron configuration(s) of said atom(s) of said element.

7. The new Atomic Model of an Atom as recited in claim 6, whereby said new atomic structure of said Atom describes the Element Helium.

8. The new Atomic Model of an Atom as recited in claim 3; for an Atom of any Element (excluding collisions); further comprising:
a. A plurality of outer electrons each orbiting said nucleus, and said common center, at the speed of light c, and therefore has a zero charge; further comprising:
i) Said plurality of outer electrons kᵢ orbiting in a plurality of orbits, i; where i ranges from i=1^{st} orbit to i=137^{th} orbit; and kᵢ is the number of electrons in the i^{th} outer orbit; and kᵢ only has values for occupied outer orbits; otherwise kᵢ is zero;
ii) Said plurality of outer electrons each having a radius rₑ/i;
iii) Said plurality of outer electrons each has an orbital radius of (1/i)(rₑ/α)) from a common center;
iv) Said plurality of outer electrons in the i^{th} orbit has a total mass ikᵢ m=i (kᵢ)(2mₑ); where m equal mass due to orbit plus mass due to spin;
v) Said plurality of outer electrons each orbiting at a frequency i*fₑ;
vi) Said plurality of outer electrons each has a spin frequency i*fₑ;
vii) Said plurality of outer electrons has a total mass of any occupied outer orbit i of kᵢ electrons is: ikᵢ (m)=((ikᵢ)(2mₑ)); where m equal mass due to orbit plus mass due to spin;
viii) The resulting total outer electron configuration mass is:
$$( 2 {m}_{e} ) ( 1 {k}_{1} + … + i {k}_{i} + … + 137 {k}_{137} = 2 {m}_{e} {\sum }_{j = 1}^{137} i ( {k}_{i} ) ;$$
for occupied outer orbits, otherwise kᵢ is zero;
b. A plurality of inner electrons within said nucleus, said plurality of inner electron(s) orbiting the common center, also at the speed of light c, and therefore have said zero charge; further comprising:
i) Said plurality of inner electrons kⱼ orbiting in a plurality of orbits j; where “j” ranges from j=1^{st} orbit to j=137^{th} orbit; and kⱼ is the number of electrons in the j^{th} inner orbit; where kⱼ only has values for occupied inner orbits, otherwise kⱼ is zero;
ii) Said plurality of inner electrons have a radius (1/j)(α²rₑ);
iii) Said plurality of inner electrons each has an orbital radius of (1/j)(αrₑ) from the common center;
iv) Said plurality of inner electrons each orbiting at a frequency j(fₑ/α²);
v) Said plurality of inner electrons each has a spin frequency j(fₑ/α²);
vi) Said plurality of inner electrons has a total mass of any occupied inner orbit j of kⱼ electrons is: jkⱼ (m/α²)=(jkⱼ)((2mₑ)/α²); where m equal mass due to orbit plus mass due to spin;
vii) The resulting total inner electron configuration mass is:
$$( 2 {m}_{e} / {α}^{2} ) ( 1 {k}_{1} + … + j {k}_{j} + … + 137 {k}_{137} ) = ( 2 {m}_{e} / {α}^{2} ) {\sum }_{j = 1}^{137} j ( {k}_{j} ) ;$$
ix. The total mass of the atom is:
$$2 {m}_{e} ( {\sum }_{i = 1}^{137} i ( {k}_{i} ) + ( 1 / {α}^{2} ) {\sum }_{j = 1}^{137} j ( {k}_{j} ) ) ;$$
c. Means for binding the atom together, whereby establishing and maintaining a stable electron configuration, by balancing the repelling and attractive forces of the atom; although other configurations may form, creating an isotope(s) for example, but they are short lived compared to the stable electron configuration(s) of said atom(s) of said element.

9. The new Atomic Model of an Atom as recited in claim 3; further comprising: said new atomic structure of any Atom; including orbits with collisions, if any; further comprising:
a. A plurality of outer electrons each on a path to orbit said nucleus, and said common center at the speed of light c, and therefore said electrons have said zero charge; further comprising:
i) Said plurality of outer electrons, kᵢ orbiting in a plurality of orbits, i; where i ranges from i=1^{st} orbit to i=137^{th} orbit; where kᵢ is the number of electrons in the i^{th} orbit; ci, is defined as an even, whole number and is the number of groups of said colliding electrons in said orbit; and kᵢ/cᵢ is defined as the number of said colliding electrons in said group; whereby kᵢ/cᵢ is zero when the ith orbit contains zero colliding electrons; further comprising:
ii) Said plurality of outer electrons kᵢ in the ith orbit, each said outer electron has a radius rₑ/i;
iii) Said plurality of outer electrons kᵢ, each said outer electron has an orbital radius of ((1/i)(rₑ/α)) from a common center;
iv) Said plurality of outer electrons kᵢ, each said outer electron orbiting at a frequency ifₑ;
v) Said plurality of outer electrons kᵢ, each said outer electron has a spin frequency ifₑ; said outer electron configuration further comprising:
i.) In orbits containing said colliding electrons, the electrons in each ci said group are equidistant from each other and distributed along the circumference of their orbit due to the binding/repelling forces on them, each ci said group of said colliding electrons alternatively traveling in a direction opposite to that of the cᵢ said group of said colliding electrons immediately adjacent to either side of it; each cᵢ said group of said colliding electrons on a path to orbit the common center, one traveling (1/cᵢ)^{th} of the circumference of the orbit, in one direction and the other, also traveling (1/cᵢ)^{th} of the circumference of the orbit, on a collision path with its mirror image at the midpoint of the distance between them;
ii.) Said cᵢ group of electrons in said outer orbit, the electrons of all groups collide with their mirror image traveling towards them, thus participating in separate but simultaneous collisions which reverses their directions, causing them to travel for (1/cᵢ)^{th} of the circumference of their orbit, towards their mirror image traveling towards them from their other side; then all cᵢ—group electrons simultaneously colliding with the cᵢ electrons on their opposite side, then after the collision reversing direction and continue repeating the simultaneous collisions again at infinitum; thus, the simultaneous reduction in each electrons' travel distance to (1/cᵢ)^{th} of the circumference of their orbit, results in the event occurring cᵢ times for each electron in the given time period;
iii.) Said cᵢ group of outer electrons in the i^{th} orbit, each said electron has a mass of imₑ due to said orbiting frequency of ifₑ; also each has a mass of imₑ due to said spin frequency of ifₑ, and because, at the collision point each said group electron travels only for (1/cᵢ)^{th} of the circumference, the event occurs cᵢ times in the given time period, which effectively results in vibrations that multiplies the orbital frequency and the spin frequency of each said electron by cᵢ times. Thus, the total outer mass of each said electrons in the ith orbit is: (i2 mₑ/electron)(cᵢ electrons)=i 2mₑ cᵢ; said collisions causes the orbiting and spin frequencies by a multiple of cᵢ because of the cᵢ radial vibrations of the electrons caused by collisions, the total outer colliding electron mass of the ith orbit of the atom is: (i 2mₑ/electron)(cᵢ electrons/collision)(cᵢ collision)=i 2mₑ(cᵢ);
iv.) For non-collision orbits, each electron in said group of outer electrons, has a mass of i mₑ due to orbiting frequency of ifₑ; and also has a mass of i mₑ due to spin frequency of ifₑ; therefore, for non-collision orbits, the total outer electron mass is:
$$( 2 {m}_{e} ) ( 1 {k}_{1} + … + i {k}_{i} + … + 137 {k}_{137} ) = ( ( 2 {m}_{e} ) {\sum }_{i = 1}^{137} i ( {k}_{i} ) ) ;$$
where kᵢ only has values greater than zero for occupied non-colliding outer orbits, otherwise the value of kᵢ is zero;
v.) For collision orbits, where cᵢ, an even number is the number of said groups of said colliding electrons in said orbits; each said colliding electron in said group of outer electrons in the i^{th} orbit, has a mass of i 2mₑ (cᵢ)² due to orbiting frequency of i2fₑ (cᵢ)²; and also has a mass of i 2mₑ (cᵢ)² due to spin frequency of i2fₑ (cᵢ)²; therefore for collision orbits, the total outer electron mass is
$$( 2 {m}_{e} ) {c}_{1} ( 1 {k}_{1} {c}_{1} ) + … + {c}_{i} ( {ik}_{i} {c}_{i} ) + … + {c}_{137} ( 137 {k}_{137} {c}_{137} ) ) = ( ( 2 {m}_{e} ) {\sum }_{i = 1}^{137} i ( {{k}_{i} ( {c}_{i} )}^{2} ) ) ;$$
where kᵢ only has values greater than zero for said occupied outer collision orbits, otherwise the value of kᵢ is zero; cᵢ is even and cᵢ only has values greater than zero for said occupied outer collision orbits, otherwise cᵢ is zero;
b. Said plurality of inner electrons within the nucleus, each said electron on a path to orbit said common center at the speed of light c, and therefore said electrons have said zero charge; further comprising:
i) Said plurality of inner electrons, kⱼ orbiting in said plurality of orbits, j; where j ranges from j=1^{st} orbit to j=137^{th} orbit; where kⱼ is the number of electrons in the j^{th} orbit, cⱼ is defined as an even, whole number and is the number of groups of said colliding electrons in said orbit; and Kⱼ/cⱼ is defined as the number of said colliding electrons in said group; where cⱼ is zero when the j^{th} orbit contains none of said colliding electrons; whereby, when cⱼ is not a whole number, said electron configuration is not handled by this claim; additional aspects of this claim, further comprising:
ii) Said plurality inner electrons kⱼ in the jth orbit, each said inner electron has a radius (1/j)(α²rₑ);
iii) Said plurality of inner electrons kⱼ, in the jth orbit, each said inner electron has an orbital radius of ((1/j)(rₑ/α)) from a common center;
iv) Said plurality of inner electrons kⱼ, in the jth orbit, each said inner electron orbiting at a frequency j(fₑ/α²);
v) Said plurality of inner electrons kⱼ, in the jth orbit, each said inner electron has a spin frequency j(fₑ/α²); said inner electron configuration further comprising:
i.) In orbits containing colliding electrons, the electrons in each said cⱼ group are equidistant from each other and distributed along the circumference of their orbit due to the binding/repelling forces on them, each cⱼ group of electron alternatively traveling in a direction opposite to that of the cⱼ group of electron immediately adjacent to either side of it; each cⱼ group of electrons on a path to orbit the common center, one traveling (1/cⱼ)^{th} of the circumference of the orbit, in one direction and the other, also traveling (1/cⱼ)^{th} of the circumference of the orbit, on a collision path with it at the midpoint of the distance between them;
ii.) Said cⱼ group of electrons in said inner orbit, the electrons of all groups collide with their mirror image traveling towards them, thus participating in separate but simultaneous collisions which reverses their directions, causing them to travel for (1/cⱼ)^{th} of the circumference of their orbit, then all group electron simultaneously colliding with the electron on their opposite side, then reversing direction and continue repeating the simultaneous collisions again at infinitum; thus, the simultaneous reduction in each electrons' travel distance to (1/cⱼ)^{th} of the circumference of their orbit results in, the event occurring cⱼ times for each electron in the given time period;
iii.) Said cⱼ group of said inner electrons in the j^{th} orbit, each said electron has a mass of jmₑ/α² due to said orbiting frequency of j(fₑ/α²); also each has a mass of jmₑ/α² due to said spin frequency of j(fₑ/α²); and because, at the collision point each said group electron travels only for (1/cⱼ)^{th} of the circumference, the event occurs cⱼ times in the given time period, which effectively results in said cⱼ radial vibrations that multiplies the orbital frequency and the spin frequency of each said electron by cⱼ times; Thus, the total inner mass of each said electron in the j^{th} orbit is:
((2 j mₑ/α²)/electron)(cⱼ electrons)=2 j (mₑ/α²) cⱼ; the total inner electron mass in the j^{th} inner orbit of the atom is:
(j(2mₑ/α²)/electron)(cⱼ electrons/collision)(cⱼ collision)=(j(2mₑ/α²)(cⱼ)²);
iv.) For non-collision inner orbits, each electron in said group of inner electrons, has a mass of j (mₑ/α²) due to orbiting frequency of j*fₑ; and also has a mass of j (mₑ/α²) due to spin frequency of j*fₑ; therefore for non-collision inner orbits, the total inner orbit electron mass is:
$$( 2 {m}_{e} / {α}^{2} ) ( 1 {k}_{1} + … + {jk}_{j} + … + 137 {k}_{137} ) = ( ( 2 {m}_{e} / {α}^{2} ) {\sum }_{j = 1}^{137} j ( {k}_{j} ) ;$$
where kⱼ only has values greater than zero for occupied outer orbits, otherwise the value of kⱼ is zero;
v.) For collision inner orbits, each electron in said group of inner electrons, has a mass of j(2mₑ/α²)(cᵢ) each due to orbiting and frequencies of j(2fₑ/α²); and also has a mass of j(2mₑ/α²) due to said radial vibration of the electrons resulting in a cᵢ frequency multiplier; therefore, for collision inner orbits, the total inner orbit electron mass is:
vi.)
$$( 2 {m}_{e} / {α}^{2} ) ( {( {c}_{1} )}^{2} ( 1 {k}_{1} ) + … + {( {c}_{j} )}^{2} ( {jk}_{j} ) + … + {( {c}_{137} )}^{2} ( 137 {k}_{137} ) ) =$$
viii.)
$$( ( 2 {m}_{e} / {α}^{2} ) {\sum }_{j = 1}^{137} j ( {k}_{j} ) {( {c}_{j} )}^{2} ) ;$$
where kⱼ only has values greater than zero for occupied inner orbits, otherwise the value of kⱼ is zero;
viii.) The total mass of the atom is:
ix.) For no collision orbits:
$$( 2 {m}_{e} ) ( {\sum }_{i = 1}^{137} i ( {k}_{i} ) + ( 1 / {α}^{2} ) {\sum }_{j = 1}^{137} j ( {k}_{j} ) ) ;$$
x.) For only collision orbits:
$$( ( 2 {m}_{e} ) ( {\sum }_{i = 1}^{137} i ( {k}_{i} ) {( {c}_{i} )}^{2} + ( i / {α}^{2} ) {\sum }_{j = 1}^{137} ( {k}_{j} ) {( {c}_{j} )}^{2} ) ) ;$$
xi.) For atom calculations that include orbits that contain both collisions and no collisions, one must use both of the above equations (labeled 1 and 2); with all applicable kᵢ, kⱼ, cᵢ, and cⱼ set equal to zero;
c. Means for binding the atom together, whereby establishing and maintaining a stable electron configuration, by balancing the repelling and attractive forces of the atom; although other configurations may form, creating an isotope(s) for example, but they are short lived compared to the stable electron configuration(s) of said atom(s) of said element.
